(19) United States
(12) Patent Application Publication
(10) Pub. No.: US 2026/0052758 A1
(43) Pub. Date: Feb. 19, 2026

(54) SEMICONDUCTOR DEVICE WITH MULTI-GATE TRANSISTOR

(71) Applicant: SAMSUNG ELECTRONICS CO., LTD., Suwon-si (KR)

(72) Inventors: Han Seong KIM, Suwon-si (KR); Kyung Ho Kim, Suwon-si (KR); Sun Ki Min, Suwon-si (KR); Gyu-Hwan Ahn, Suwon-si (KR); Kang Sub Yim, Suwon-si (KR)

(73) Assignee: SAMSUNG ELECTRONICS CO., LTD., Suwon-si (KR)

(21) Appl. No.: 19/027,271

(22) Filed: Jan. 17, 2025

(30) Foreign Application Priority Data
Aug. 19, 2024 (KR) 10-2024-0110770

(51) Int. Cl. H10D 84/40; H10D 84/01

(52) U.S. Cl. CPC H10D 84/40; H10D 84/0107

(57) ABSTRACT

Provided is a semiconductor device and method of manufacturing same, the semiconductor device including: a first active pattern which extends in a first direction; an isolation gate electrode on the first active pattern, wherein the isolation gate electrode includes an insulating material and extends in a second direction intersecting the first direction; an isolation capping pattern on the isolation gate electrode; a first recess in the isolation capping pattern and the isolation gate electrode; and a first insulating pattern inside the first recess, wherein the first insulating pattern includes a first liner film and a first filling film, wherein the first liner film includes a material different from the isolation gate electrode and the first filling film.

### CROSS-REFERENCE TO RELATED APPLICATION

This application claims priority to Korean Patent Application No. 10-2024-0110770, filed on Aug. 19, 2024 in the Korean Intellectual Property Office, the contents of which are herein incorporated by reference in its entirety.

### BACKGROUND

### 1. Field

The present disclosure relates to a semiconductor device.

### 2. Description of the Related Art

For a variety of reasons, it is desirable to increase the density of features included in a semiconductor device. One scaling technology for increasing density of a semiconductor device is the use of a multi-gate transistor in which a multi-channel active pattern (or a silicon body) having a fin or nanowire shape is formed on a substrate and a gate is formed on a surface of the multi-channel active pattern. Since such a multi-gate transistor utilizes a three-dimensional channel, scaling is more easily performed. Further, even if a gate length of the multi-gate transistor is not increased, the current control capability may be improved. Furthermore, a SCE (short channel effect) in which potential of a channel region is influenced by a drain voltage may be effectively suppressed.

### SUMMARY

Provided is a semiconductor device with improved product reliability.

According to an aspect of the disclosure, a semiconductor device includes: a first active pattern which extends in a first direction; an isolation gate electrode on the first active pattern, wherein the isolation gate electrode comprises an insulating material and extends in a second direction intersecting the first direction; an isolation capping pattern on the isolation gate electrode; a first recess in the isolation capping pattern and the isolation gate electrode; and a first insulating pattern inside the first recess, wherein the first insulating pattern comprises a first liner film and a first filling film, wherein the first liner film comprises a material different from the isolation gate electrode and the first filling film.

According to an aspect of the disclosure, a semiconductor device includes: a plurality of first active patterns which extend in a first direction, wherein the plurality of first active patterns are spaced apart from each other in a second direction; an isolation gate electrode on the plurality of first active patterns, wherein the isolation gate electrode extends in the second direction; a liner film which extends along the isolation gate electrode; a filling film which extends along the liner film; a plurality of second active patterns which extend in the first direction, wherein the plurality of second active patterns are spaced apart from each other in the second direction; and a gate structure on the plurality of second active patterns, wherein the gate structure extends in the second direction, wherein the gate structure fills gaps formed between second active patterns, among the plurality of second active patterns, that are adjacent to one another in the second direction, and wherein the isolation gate electrode, the liner film, and the filling film fill a part of gaps formed between first active patterns, among the plurality of first active patterns, that are adjacent to one another in the second direction.

According to an aspect of the disclosure, a semiconductor device includes: a first active pattern; an isolation gate structure which intersects the first active pattern, wherein the isolation gate structure comprises a first region and a second region; a recess in at least one of the first region and the second region; and an insulating pattern extending along the recess, wherein the isolation gate structure comprises an isolation gate electrode and an isolation capping pattern on the isolation gate electrode, wherein an upper face of the first region of the isolation gate structure is defined by the isolation capping pattern, and wherein an upper face of the second region of the isolation gate structure is defined by the isolation gate electrode.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of certain embodiments of the present disclosure will become more apparent from the following description taken in conjunction with the accompanying drawings, in which:

FIG. 1 is a an exemplary layout view for explaining a semiconductor device according to one or more embodiments;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIG. 5 is a cross-sectional view taken along line D-D′ of FIG. 1;

FIG. 6 is a cross-sectional view for explaining the semiconductor device according to one or more embodiments;

FIG. 7 is an exemplary layout view for explaining the semiconductor device according to one or more embodiments;

FIG. 8 is a cross-sectional view taken along line A-A′ of FIG. 7;

FIG. 9 is an exemplary layout view for explaining the semiconductor device according to one or more embodiments;

FIG. 10 is a cross-sectional view taken along line A-A′ of FIG. 9;

FIGS. 11 through 16 are exemplary cross-sectional views for explaining the semiconductor device according to one or more embodiments; and

FIGS. 17 through 42 are intermediate stage diagrams for explaining a method for fabricating the semiconductor device according to one or more embodiments.

### DETAILED DESCRIPTION

In the following description, like reference numerals refer to like elements throughout the specification.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

Although drawings of the semiconductor device according to one or more embodiments show a fin-shaped transistor (FinFET) including a channel region of a fin-shaped pattern shape, a transistor including a nanowire or a nanosheet, and a MBCFET™ (Multi-Bridge Channel Field Effect Transistor) as an example, the disclosure is not limited thereto. The semiconductor device according to one or more embodiments may include a tunneling transistor (tunneling FET), a three-dimensional (3D) transistor or a vertical transistor (Vertical FET). The semiconductor device according to one or more embodiments may include a planar transistor. In addition, the technical idea of the present disclosure may be applied to a transistor based on a two-dimensional material (2D material based FETs) and a heterostructure thereof. Further, the semiconductor device according to one or more embodiments may also include a bipolar junction transistor, a laterally diffused metal oxide semiconductor (LDMOS), or the like.

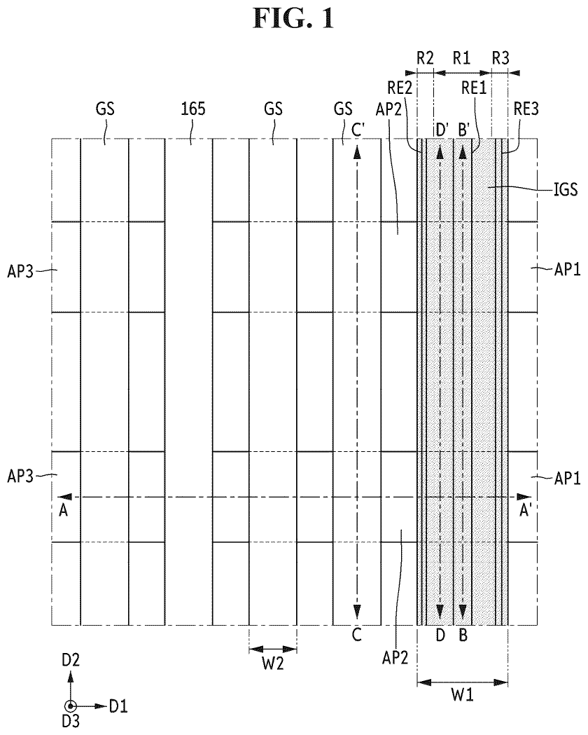

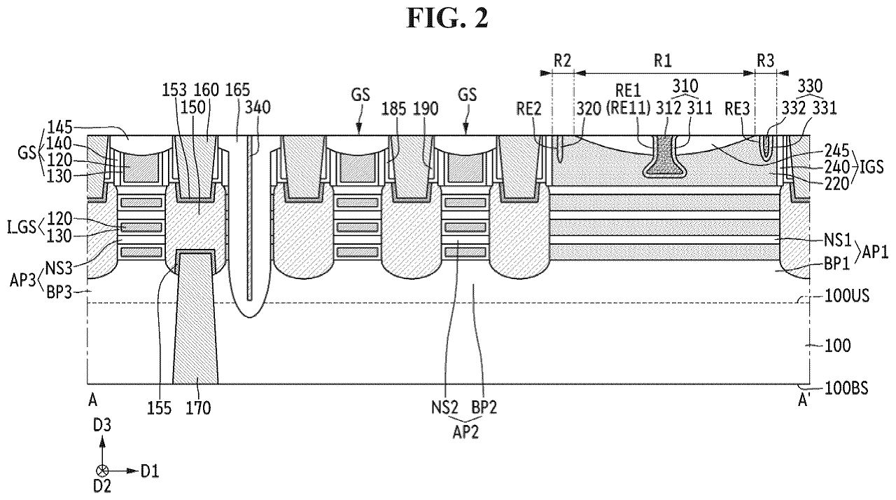

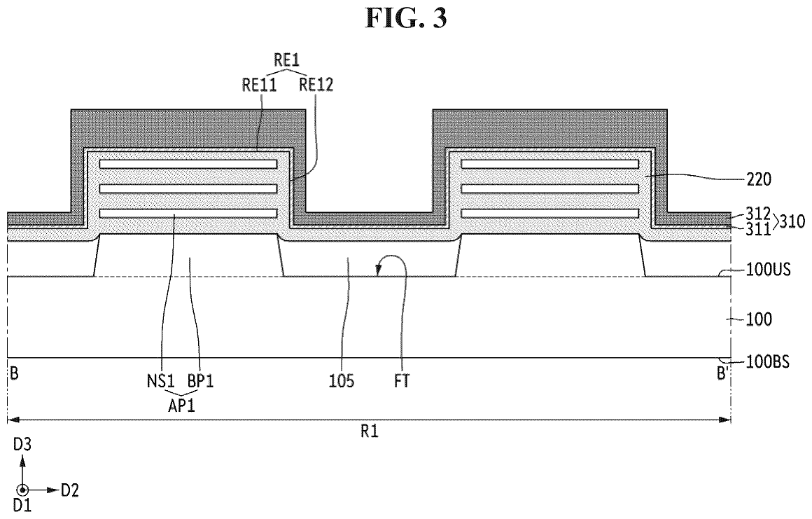

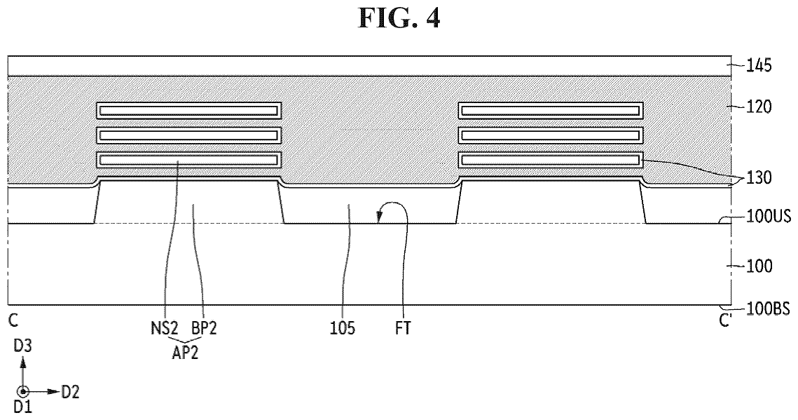

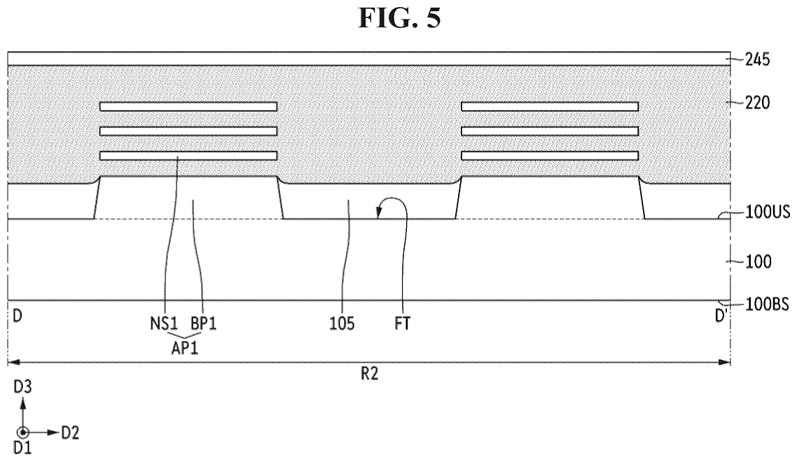

FIG. 1 is an exemplary layout view for explaining a semiconductor device according to one or more embodiments. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1. FIG. 5 is a cross-sectional view taken along line D-D′ of FIG. 1.

Referring to FIGS. 1 through 5, the semiconductor device according to one or more embodiments may include a substrate 100, a first active pattern AP1, a second active pattern AP2, a third active pattern AP3, an isolation gate structure IGS, a gate structure GS, a source/drain pattern 150, a front contact silicide film 153, a back contact silicide film 155, a front source/drain contact 160, an element isolation pattern 165, a back source/drain contact 170, a source/drain etching stop film 185, and a front interlayer insulating film 190.

The substrate 100 may include a first face 100US and a second face 100BS which are opposite to each other in a third direction D3. Here, a first direction D1 and a second direction D2 intersect each other, and are aligned with the first face 100US. The third direction D3 intersects the first direction D1 and the second direction D2, and is perpendicular to the first face 100US. An upper face, a lower face, an upper part, and a lower part are defined relative to the third direction D3.

The substrate 100 may be a silicon substrate or a silicon-on-insulator (SOI). Alternatively, the substrate 100 may include silicon-germanium, silicon germanium on insulator (SGOI), indium antimonide, lead telluride, indium arsenide, indium phosphide, gallium arsenide or gallium antimonide, however the disclosure is not limited thereto.

The first active pattern AP1, the second active pattern AP2, and the third active pattern AP3 may be formed on the first face 100US of the substrate 100. The first active pattern AP1, the second active pattern AP2, and the third active pattern AP3 may each extend along the first direction D1. The first active pattern AP1, the second active pattern AP2, and the third active pattern AP3 may each be spaced apart from each other in the second direction D2.

A diode (e.g., a gate bounded diode) may be formed in the first active pattern AP1, and a transistor may be formed in the second active pattern AP2 and the third active pattern AP3.

The first active pattern AP1, the second active pattern AP2, and the third active pattern AP3 may each be a multi-channel active pattern. For example, the first active pattern AP1 may include a first lower pattern BP1 and a plurality of first sheet patterns NS1. The second active pattern AP2 may include a second lower pattern BP2 and a plurality of second sheet patterns NS2. The third active pattern AP3 may include a third lower pattern BP3 and a plurality of third sheet patterns NS3. In the semiconductor device according to one or more embodiments, the first active pattern AP1, the second active pattern AP2, and the third active pattern AP3 may each be an active pattern including a nanosheet or a nanowire.

The first lower pattern BP1, the second lower pattern BP2, and the third lower pattern BP3 may protrude from the first face 100US of the substrate 100. The first lower pattern BP1, the second lower pattern BP2, and the third lower pattern BP3 may each be a fin-shaped pattern. The first lower pattern BP1, the second lower pattern BP2, and the third lower pattern BP3 may each extend long in the first direction D1. The third lower pattern BP3 and the second lower pattern BP2 may be spaced apart from each other in the first direction D1. The second lower pattern BP2 and the first lower pattern BP1 may be spaced apart from each other in the first direction D1.

The first lower pattern BP1, the second lower pattern BP2, and the third lower pattern BP3 may be defined by a fin trench FT. For example, the first face 100US of the substrate 100 may be a bottom face of a fin trench FT. The side walls of the first lower pattern BP1, the second lower pattern BP2, and the third lower pattern BP3 may each be defined by the fin trench FT.

A plurality of first sheet patterns NS1 may be disposed on the first lower pattern BP1. The plurality of first sheet patterns NS1 may be spaced apart from the first lower pattern BP1 in the third direction D3. A plurality of second sheet patterns NS2 may be disposed on the second lower pattern BP2. The plurality of second sheet patterns NS2 may be spaced apart from the second lower pattern BP2 in the third direction D3. A plurality of third sheet patterns NS3 may be disposed on the third lower pattern BP3. The plurality of third sheet patterns NS3 may be spaced apart from the third lower pattern BP3 in the third direction D3.

Each of the three first sheet patterns NS1, the three second sheet patterns NS2, and the three third sheet patterns NS3 is shown as being disposed in the third direction D3, but this is only for convenience of explanation, but the disclosure is not limited thereto.

Each of the first lower pattern BP1, the second lower pattern BP2, and the third lower pattern BP3 may include silicon or germanium, which is an elemental semiconductor material. Alternatively, each of the first lower pattern BP1, the second lower pattern BP2, and the third lower pattern BP3 may include a compound semiconductor, and may include, for example, a group IV-IV compound semiconductor or a group III-V compound semiconductor. The group IV-IV compound semiconductor may include, for example, a binary compound or a ternary compound including at least two or more of carbon (C), silicon (Si), germanium (Ge) and tin (Sn), or a compound obtained by doping these elements with a group IV element. The group III-V compound semiconductor may be, for example, at least one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

Each of the first sheet pattern NS1, the second sheet pattern NS2, and the third sheet pattern NS3 may include one of silicon or germanium which is an elemental semiconductor material, a group IV-IV compound semiconductor or a group III-V compound semiconductor. A width of each of the first sheet pattern NS1, the second sheet pattern NS2, and the third sheet pattern NS3 in the second direction D2 may increase or decrease in proportion to a width of each of the first lower pattern BP1, the second lower pattern BP2, and the third lower pattern BP3 in the second direction D2. Taking the first sheet pattern NS1 as an example, although the widths in the second direction D2 of each of the first sheet patterns NS1 disposed on the first lower pattern BP1 are shown as being the same, the disclosure is not limited thereto.

The field insulating film 105 may be disposed on the first face 100US of the substrate 100. The field insulating film 105 may fill at least a part of the fin trench FT that separates the first to third lower patterns BP1, BP2, and BP3. The field insulating film 105 may be disposed on the side walls of the first to third lower patterns BP1, BP2, and BP3. As an example, the field insulating film 105 may cover the entire side walls of the first to third lower patterns BP1, BP2, and BP3. Alternatively, the field insulating film 105 may cover a part of the side walls of the first to third lower patterns BP1, BP2, and BP3. That is, a part of the first to third lower patterns BP1, BP2, and BP3 may protrude in the third direction D3 beyond an upper face of the field insulating film 105.

In one or more embodiments, the field insulating film 105 does not cover the upper faces of the first to third lower patterns BP1, BP2, and BP3. Each of the first to third sheet patterns NS1, NS2, and NS3 may be disposed to be higher than the upper face of the field insulating film 105 on the basis of the first face 100US of the substrate 100.

The field insulating film 105 may include, for example, an oxide film, a nitride film, an oxynitride film or a combination thereof. Although the field insulating film 105 is shown as being a single film, this is only for convenience of explanation, and the disclosure is not limited thereto.

The isolation gate structure IGS may be disposed on the substrate 100 and the field insulating film 105. The isolation gate structure IGS may be disposed on the first face 100US of the substrate 100. The isolation gate structure IGS may extend long in the second direction D2. Although the semiconductor device is shown as including one isolation gate structure IGS, this is only for convenience of explanation, and the disclosure is not limited thereto. For example, a plurality of isolation gate structures IGS spaced apart from each other in the first direction D1 may be disposed on the first active pattern AP1.

The isolation gate structure IGS may be disposed on the first active pattern AP1. The isolation gate structure IGS may intersect the first active pattern AP1. The isolation gate structure IGS may be disposed on the first lower pattern BP1. The isolation gate structure IGS may surround the first sheet pattern NS1.

The isolation gate structure IGS may include, for example, an isolation gate electrode 220, an isolation spacer 240, and an isolation capping pattern 245.

The isolation gate electrode 220 may be disposed on the first active pattern AP1 and the field insulating film 105. The isolation gate electrode 220 may intersect the first active pattern AP1. The isolation gate electrode 220 may be disposed on the first lower pattern BP1. The isolation gate electrode 220 may intersect the first lower pattern BP1. The isolation gate electrode 220 may surround the first sheet pattern NS1.

The isolation gate electrode 220 may be disposed between the first sheet patterns NS1 adjacent to each other in the third direction D3, and between the first lower pattern BP1 and the first sheet pattern NS1 that are adjacent to each other in the third direction D3. The isolation gate electrode 220 may be disposed between an upper face of the first lower pattern BP1 and a lower face of the first sheet pattern NS1 that face each other in the third direction D3, and between an upper face of the first sheet pattern NS1 and a lower face of the first sheet pattern NS1 that face each other in the third direction D3.

The isolation gate electrode 220 may include an insulating material. The isolation gate electrode 220 may include, for example, silicon oxide.

The isolation spacer 240 may be disposed on a side wall of the isolation gate electrode 220. The isolation spacer 240 may not be disposed between the first lower pattern BP1 and the first sheet pattern NS1, and between the first sheet patterns NS1 adjacent to each other in the third direction D3.

The isolation capping pattern 245 may be disposed on the isolation gate electrode 220. The upper face of the isolation capping pattern 245 may be disposed on the same plane as the upper face of the front interlayer insulating film 190. Unlike the shown example, the isolation capping pattern 245 may be disposed between the isolation spacers 240.

In one or more embodiments, the isolation gate electrode 220 may come into contact with the source/drain pattern 150.

In one or more embodiments, the isolation gate structure IGS may further include an inner spacer including an insulating material between the isolation gate electrode 220 and the source/drain pattern 150. The inner spacer may be disposed between the first sheet patterns NS1 adjacent to each other the third direction D3, and between the first sheet pattern NS1 and the first lower pattern BP1. The inner spacer may come into contact with the source/drain pattern 150.

The isolation capping pattern 245 may be disposed on a part of the isolation gate electrode 220. The isolation capping pattern 245 may expose a part of the upper face of the isolation gate electrode 220. The isolation gate structure IGS may include a first region R1 in which the isolation capping pattern 245 is disposed, and a second region R2 and a third region R3 in which the isolation capping pattern 245 is not disposed. The first region R1 of the isolation gate structure IGS may include an isolation gate electrode 220 and an isolation capping pattern 245 that overlap in the third direction D3. The second region R2 and the third region R3 of the isolation gate structure IGS may include the isolation gate electrode 220. An upper face of the first region R1 of the isolation gate structure IGS may be defined by the isolation capping pattern 245. An upper face of the second region R2 and an upper face of the third region R3 of the isolation gate structure IGS may be defined by the isolation gate electrode 220. The first region R1 may be disposed between the second region R2 and the third region R3.

The isolation gate structure IGS may include recesses RE1, RE2, and RE3 formed in at least one of the first region R1, the second region R2, and the third region R3.

In one or more embodiments, the isolation gate structure IGS may include a first recess RE1 formed in the first region R1, a second recess RE2 formed in the second region R2, and a third recess RE3 formed in a third region R3.

The first recess RE1 may be formed in the isolation capping pattern 245 and the isolation gate electrode 220. The first recess RE1 may extend from an upper face of the isolation capping pattern 245 into the isolation gate electrode 220. The lowermost face of the first recess RE1 may be disposed inside the isolation gate electrode 220.

The first recess RE1 may extend in the second direction D2 in the first region R1. The first recess RE1 may include a first portion RE11 that overlaps the first active pattern AP1 in the third direction D3, and a second portion RE12 that overlaps the field insulating film 105 in the third direction D3. A depth of the first portion RE11 may be shallower than a depth of the second portion RE12 in the third direction D3. The lowermost face of the first portion RE11 may be disposed above the lowermost face of the second portion RE12. The width of the lower part of the first portion RE11 in the first direction D1 may be greater than the width of the upper part of the first portion RE11 in the first direction D1. The second portion RE12 may be formed between the first active patterns AP1 adjacent to each other in the second direction D2.

The first insulating pattern 310 may fill a part of the first recess RE1. The first insulating pattern 310 may fill the first portion RE11 of the first recess RE1, and may fill a part of the second portion RE12 of the first recess RE1. In a cross-sectional view in which the first active pattern AP1 is taken along the first direction D1, the first insulating pattern 310 may fill the first recess RE1. The isolation gate electrode 220 and the first insulating pattern 310 fill a part between the first active patterns AP1 adjacent to each other in the second direction D2.

The first insulating pattern 310 may include a first liner film 311 and a first filling film 312. The first liner film 311 may extend along the first recess RE1. The first filling film 312 may extend along the first liner film 311. The first filling film 312 may fill the first portion RE11 of the first recess RE1 on the first liner film 311. In the cross-sectional view in which the first active pattern AP1 is taken along the first direction D1, the first filling film 312 may fill the first recess RE1 on the first liner film 311.

The second recess RE2 and the third recess RE3 may be formed in the isolation gate electrode 220. The second recess RE2 and the third recess RE3 extend from the upper face of the isolation gate electrode 220 into the isolation gate electrode 220. The lowermost face of the second recess RE2 and the lowermost face of the third recess RE3 are disposed inside the isolation gate electrode 220.

The second recess RE2 may extend in the second direction D2 in the second region R2. The second recess RE2 may include a first portion that overlaps the first active pattern AP1 in the third direction D3, and a second portion that overlaps the field insulating film 105 in the third direction D3. A depth of the first portion of the second recess RE2 in the third direction D3 may be shallower than a depth of the second portion of the second recess RE2. The lowermost face of the first portion of the second recess RE2 may be disposed above the lowermost face of the second portion of the second recess RE2. A cross-sectional view in which the second recess RE2 is taken in the second direction D2 may be similar to that of FIG. 3. The second recess RE2 of FIG. 2 is the first portion of the second recess RE2.

The width of the second recess RE2 in the first direction D1 may be smaller than the width of the first recess RE1 in the first direction D1. The depth of the second recess RE2 in the third direction D3 may be shallower than the depth of the first recess RE1 in the third direction D3, on the basis of the upper face of the isolation gate structure IGS.

The second insulating pattern 320 may fill a part of the second recess RE2. The second insulating pattern 320 may fill the first portion of the second recess RE2, and may fill a part of the second portion of the second recess RE2. In the cross-sectional view in which the first active pattern AP1 is taken along the first direction D1, the second insulating pattern 320 may fill the second recess RE2.

In one or more embodiments, the second insulating pattern 320 may be a single film. The second insulating pattern 320 may extend along the second recess RE2.

The third recess RE3 may extend in the second direction D2 in the third region R3. The third recess RE3 may include a first portion that overlaps the first active pattern AP1 in the third direction D3, and a second portion that overlaps the field insulating film 105 in the third direction D3. The depth of the first portion of the third recess RE3 in the third direction D3 may be shallower than the depth of the second portion of the third recess RE3. The lowermost face of the first portion of the third recess RE3 may be located above the lowermost face of the second portion of the third recess RE3. A cross-sectional view in which the third recess RE3 is taken in the second direction D2 may be similar to that of FIG. 3. The third recess RE3 of FIG. 2 is the first portion of the third recess RE3.

A width of the third recess RE3 in the first direction D1 may be smaller than the width of the first recess RE1 in the first direction D1. The depth of the third recess RE3 in the third direction D3 may be shallower than the depth of the first recess RE1 in the third direction D3, on the basis of the upper face of the isolation gate structure IGS. The width of the second recess RE2 in the first direction D1 may be smaller than the width of the third recess RE3 in the first direction D1.

A third insulating pattern 330 may fill a part of the third recess RE3. The third insulating pattern 330 may fill the first portion of the third recess RE3, and may fill a part of the second portion of the third recess RE3. In the cross-sectional view in which the first active pattern AP1 is taken along the first direction D1, the third insulating pattern 330 may fill the third recess RE3.

In one or more embodiments, the third insulating pattern 330 may be a multi-layer film. The third insulating pattern 330 may include a second liner film 331 and a second filling film 332. The second liner film 331 may extend along the third recess RE3. The second filling film 332 may extend along the second liner film 331. The second filling film 332 may fill the first portion of the third recess RE3 on the second liner film 331. In the cross-sectional view in which the first active pattern AP1 is taken along the first direction D1, the second filling film 332 may fill the third recess RE3 on the second liner film 331.

The first to third insulating patterns 310, 320, and 330 may each include an insulating material.

The first liner film 311 may include a material different from the isolation gate electrode 220 and the first filling film 312. The first liner film 311 may include a material having an etching selectivity with respect to the isolation gate electrode 220 and the first filling film 312. The etching resistance of the first liner film 311 to DHF (diluted hydrofluoric acid) may be greater than the etching resistance to the isolation gate electrode 220 and the etching resistance to the first filling film 312. The first liner film 311 may include, for example, SiN, SiCN, SiOCN, SiCOH, SiOCH, or the like.

The first liner film 311, the second liner film 331, and the second insulating pattern 320 may include the same material.

The first filling film 312 and the second filling film 332 may include the same material. The first filling film 312 and the second filling film 332 may include the same material as the isolation gate electrode 220. The first filling film 312 and the second filling film 332 may include, for example, silicon oxide.

The gate structure GS may be disposed on the substrate 100 and the field insulating film 105. The gate structure GS may be disposed on the first face 100US of the substrate 100. The gate structure GS may extend long in the second direction D2. The gate structures GS may be spaced apart from each other in the first direction D1. The gate structures GS may be adjacent to each other in the first direction D1.

The gate structure GS may be disposed on each of the second active pattern AP2 and the third active pattern AP3. The gate structure GS may intersect each of the second active pattern AP2 and the third active pattern AP3.

A width W1 of the isolation gate structure IGS in the first direction D1 may be greater than a width W2 of the gate structure GS in the first direction D1. The width of the isolation gate electrode 220 in the first direction D1 may be greater than the width of the gate electrode 120 in the first direction D1. The width of the first lower pattern BP1 in the first direction D1 may be greater than the width of the second lower pattern BP2 in the first direction D1 and the width of the third lower pattern BP3 in the first direction D1. The width of the first sheet pattern NS1 in the first direction D1 may be greater than the width of the second sheet pattern NS2 in the first direction D1 and the width of the third sheet pattern NS3 in the first direction D1.

The gate structure GS may be disposed on the second lower pattern BP2. The gate structure GS may surround the second sheet pattern NS2. The gate structure GS may be disposed on the third lower pattern BP3. The gate structure GS may surround the third sheet pattern NS3.

The gate structure GS may include, for example, a gate electrode 120, a gate insulating film 130, a gate spacer 140, and a gate capping pattern 145.

The gate structure GS may include an inner gate structure I_GS. The inner gate structure I_GS may be located between the second sheet patterns NS2 adjacent to each other in the third direction D3, and between the second lower pattern BP2 and the second sheet pattern NS2 that are adjacent to each other in the third direction D3. The inner gate structure I_GS may be located between the upper face of the second lower pattern BP2 and the lower face of the second sheet pattern NS2 that face each other in the third direction D3, and between the upper face of the second sheet pattern NS2 and the lower face of the second sheet pattern NS2 that face each other in the third direction D3. The inner gate structure I_GS may be located between the third sheet patterns NS3 adjacent to each other in the third direction D3, and between the third lower pattern BP3 and the third sheet pattern NS3 that are adjacent to each other in the third direction D3. The inner gate structure I_GS may be disposed between the upper face of the third lower pattern BP3 and the lower face of the third sheet pattern NS3 that face each other in the third direction D3, and between the upper face of the third sheet pattern NS3 and the lower face of the third sheet pattern NS3 that face each other in the third direction D3.

The inner gate structure I_GS may include a gate electrode 120 and a gate insulating film 130. The number of inner gate structures I_GS included in one gate structure GS may be identical to the number of the plurality of sheet patterns (e.g., the second sheet pattern NS2 or the third sheet pattern NS3).

In one or more embodiments, the inner gate structure I_GS may come into contact with the source/drain pattern 150.

In one or more embodiments, an inner spacer including an insulating material may be further included between the inner gate structure I_GS and the source/drain pattern 150. The inner spacer may be disposed between the second sheet patterns NS2 adjacent to each other in the third direction D3, between the second sheet pattern NS2 and the second lower pattern BP2, between the third sheet patterns NS3 adjacent to each other in the third direction D3, and between the third sheet pattern NS3 and the third lower pattern BP3. The inner spacer may come into contact with the source/drain pattern 150. The gate electrode 120 may be disposed on the second lower pattern BP2. The gate electrode 120 may intersect the second lower pattern BP2. The gate electrode 120 may surround the second sheet pattern NS2. The gate electrode 120 may be disposed on the third lower pattern BP3. The gate electrode 120 may intersect the third lower pattern BP3. The gate electrode 120 may surround the third sheet pattern NS3.

The gate electrode 120 may include at least one of a metal, a conductive metal nitride, a metal silicide, a doped semiconductor material, a conductive metal oxide, and a conductive metal oxynitride. The gate electrode 120 may include, for example, but not limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxide and the conductive metal oxynitride may include, but not limited to, an oxidized form of the aforementioned materials.

The gate insulating film 130 may extend along the upper face of the field insulating film 105 and the first face 100US of the substrate 100. The gate insulating film 130 may surround a plurality of second sheet patterns NS2. The gate insulating film 130 may surround a plurality of third sheet patterns NS3. The gate insulating film 130 may be disposed along the periphery of the second sheet pattern NS2 and the periphery of the third sheet pattern NS3. The gate insulating film 130 may be disposed between the gate electrode 120 and the second sheet pattern NS2. The gate insulating film 130 may be disposed between the gate electrode 120 and the third sheet pattern NS3. The gate electrode 120 may be disposed on the gate insulating film 130.

The gate insulating film 130 may include silicon oxide, silicon oxynitride, silicon nitride or a high dielectric constant material having a dielectric constant greater than that of silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although the gate insulating film 130 is shown as being a single film, this example is only for convenience of explanation, and the disclosure is not limited thereto. The gate insulating film 130 may include a plurality of films. The gate insulating film 130 may include an interfacial layer and a high dielectric constant insulating film disposed between the second sheet pattern NS2 and the gate electrode 120, and between the third sheet pattern NS3 and the gate electrode 120. For example, the interfacial layer may not be formed along the profile of the upper face of the field insulating film 105.

The semiconductor device according to one or more embodiments may include an NC (Negative Capacitance) FET that uses a negative capacitor. For example, the gate insulating film 130 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease compared to the capacitance of each of the individual capacitors. On the other hand, if at least one of the capacitances of two or more capacitors connected in series has a negative value, the overall capacitance may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. A thickness of the ferroelectric material film may be, for example, but not limited to, 0.5 to 10 nm. Since a critical thickness that exhibits the ferroelectric properties may vary for each ferroelectric material, the thickness of the ferroelectric material film may vary depending on the ferroelectric material.

As an example, the gate insulating film 130 may include one ferroelectric material film. As another example, the gate insulating film 130 may include a plurality of ferroelectric material films spaced apart from each other. The gate insulating film 130 may have a stacked film structure in which the plurality of ferroelectric material films and the plurality of paraelectric material films are alternately stacked.

The gate spacer 140 may be disposed on the side wall of the first gate electrode 120. The gate spacer 140 may not be disposed between the second lower pattern BP2 and the second sheet pattern NS2, and between the third sheet pattern NS3 adjacent to each other in the third direction D3.

Each of the gate spacer 140 and the isolation spacer 240 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although the gate spacer 140 is shown as being a single film, this example is only for convenience of explanation and the disclosure is not limited thereto.

The gate capping pattern 145 may be disposed on the gate electrode 120. The upper face of the gate capping pattern 145 may be disposed on the same plane as the upper face of the front interlayer insulating film 190. Unlike the shown example, the gate capping pattern 145 may be disposed between the gate spacers 140.

Each of the gate capping pattern 145 and the isolation capping pattern 245 may include, for example, at least one of silicon nitride (SiN), silicon oxynitride (SiON), silicon carbonitride (SiCN), silicon oxycarbonitride (SiOCN), and combinations thereof.

Each of the gate capping pattern 145 and the isolation capping pattern 245 may include a material having an etching selectivity with respect to the front interlayer insulating film 190.

The source/drain patterns 150 may be disposed on each of the first to third active patterns AP1, AP2, and AP3. The source/drain pattern 150 may be disposed on each of the first to third lower patterns BP1, BP2, and BP3. The source/drain pattern 150 may be disposed on at least one side of the isolation gate structure IGS in the first direction D1 and at least one side of the gate structure GS in the first direction D1. The source/drain pattern 150 may be disposed between the isolation gate structure IGS and the gate structure GS that are adjacent to each other in the first direction D1. The source/drain pattern 150 may be disposed between the gate structures GS adjacent to each other in the first direction D1. The source/drain pattern 150 may come into contact with each of the first to third active patterns AP1, AP2, and AP3. The source/drain pattern 150 may come into contact with each of the first to third sheet patterns NS1, NS2, and NS3.

The source/drain pattern 150 may be provided as a source/drain region of each transistor that uses the second and third sheet patterns NS2 and NS3 as a channel region. The source/drain pattern 150 may be provided as a source/drain region of a diode formed in the first active pattern AP1.

The source/drain pattern 150 may include an epitaxial pattern. The source/drain pattern 150 may include a semiconductor material.

The source/drain pattern 150 may include, for example, silicon or germanium which is an elemental semiconductor material. Also, the source/drain pattern 150 may include a binary compound or a ternary compound including at least two or more of carbon (C), silicon (Si), germanium (Ge), and tin (Sn), or a compound obtained by doping these elements with a group IV element. The source/drain pattern 150 may include an epitaxial film made of a semiconductor material. Although the source/drain pattern 150 is shown as being a single film, this example is only for convenience of explanation only and the disclosure is not limited thereto.

The source/drain pattern 150 may include a dopant doped in the semiconductor material. The source/drain pattern 150 may include a p-type dopant or an n-type dopant. The p-type dopant may include, for example, but not limited to, at least one of boron (B) and gallium (Ga). The n-type dopant may include, but not limited to, at least one of phosphorus (P), arsenic (As), antimony (Sb) and bismuth (Bi).

The front interlayer insulating film 190 may be disposed on the field insulating film 105 and the source/drain pattern 150. The front interlayer insulating film 190 may not cover the upper face of the gate capping pattern 145 and the upper face of the isolation capping pattern 245. For example, the upper face of the front interlayer insulating film 190 may be disposed on the same plane as the upper face of the gate capping pattern 145 and the upper face of the isolation capping pattern 245.

The front interlayer insulating film 190 may include, for example, at least one of silicon oxide, silicon nitride, silicon oxynitride and a low dielectric constant material.

The source/drain etching stop film 185 may extend along the profile of the source/drain pattern 150. The source/drain etching stop film 185 may be disposed between the source/drain pattern 150 and the front interlayer insulating film 190. The source/drain etching stop film 185 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), and combinations thereof.

The element isolation pattern 165 may be disposed on the first face 100US of the substrate 100. The element isolation pattern 165 may extend in the second direction D2. The element isolation pattern 165 may be disposed between the second active pattern AP2 and the third active pattern AP3. The element isolation pattern 165 may be disposed between the source/drain pattern 150 disposed in the second active pattern AP2 and the source/drain pattern 150 disposed in the third active pattern AP3. The source/drain pattern 150 may be disposed between the element isolation pattern 165 and the gate structure GS that are adjacent to each other. The element isolation pattern 165 may separate the first lower pattern BP1 and the second lower pattern BP2.

The element isolation pattern 165 is shown as being disposed between the second active pattern AP2 and the third active pattern AP3, but this example is only for convenience of explanation and the disclosure is not limited thereto. That is, the element isolation pattern 165 may be disposed between the first active pattern AP1 and the second active pattern AP2, and may separate the first lower pattern BP1 and the second lower pattern BP2.

The element isolation pattern 165 may include an insulating material. The element isolation pattern 165 may include at least one of, for example, silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. The element isolation pattern 165 is shown as being a single film, but the disclosure is not limited thereto.

A residual insulating pattern may be disposed between the element isolation pattern 165 and the source/drain pattern 150. The residual insulating pattern may include the same material as the gate insulating film 130.

In one or more embodiments, the element isolation pattern 165 may include an insulating pattern 340 therein. The insulating pattern 340 may extend from an upper face of the element isolation pattern 165 into the element isolation pattern 165. The insulating pattern 340 may include the same material as the first liner film 311.

The front source/drain contact 160 may extend in the third direction D3. The front source/drain contact 160 may be connected to the source/drain pattern 150. The front source/drain contact 160 may be disposed inside the front interlayer insulating film 190 and the source/drain pattern 150. A part of the front source/drain contact 160 may be disposed inside the source/drain pattern 150. The front source/drain contact 160 does not penetrate the lower patterns BP1, BP2, and BP3.

The front contact silicide film 153 may be disposed between the front source/drain contact 160 and the source/drain pattern 150. The front contact silicide film 153 may include a metal silicide material.

The back source/drain contact 170 may extend in the third direction D3. The back source/drain contact 170 may be connected to the source/drain pattern 150. A part of the back source/drain contact 170 may be disposed inside the substrate 100, the lower patterns BP1, BP2, and BP3, and the source/drain pattern 150.

The back contact silicide film 155 may be disposed between the back source/drain contact 170 and the source/drain pattern 150. The back contact silicide film 155 may include a metal silicide material.

Although each of the front source/drain contact 160 and the back source/drain contact 170 is shown to have a single conductive film structure, the disclosure is not limited thereto. Unlike the shown example, at least one of the front source/drain contact 160 and the back source/drain contact 170 may have a multiple conductive film structure including a contact barrier film and a contact filling film.

Each of the front source/drain contact 160 and the back source/drain contact 170 may include at least one of, for example, a metal, a conductive metal nitride, a conductive metal carbide, a conductive metal oxide, a conductive metal carbonitride, and a two-dimensional Material.

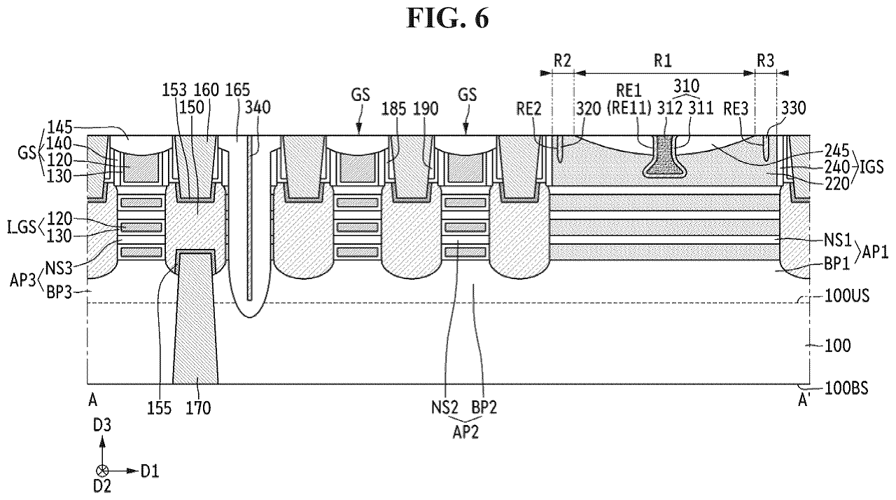

FIG. 6 is a cross-sectional view for explaining a semiconductor device according to one or more embodiments. For reference, FIG. 6 is a cross-sectional view taken along A-A′ of FIG. 1. For convenience of explanation, differences from the description using FIGS. 1 through 5 will be mainly described.

Referring to FIG. 6, in the semiconductor device according to one or more embodiments, the third insulating pattern 330 may be a single film. The third insulating pattern 330 may extend along the third recess RE3.

The third insulating pattern 330 may include the same material as the first liner film 311.

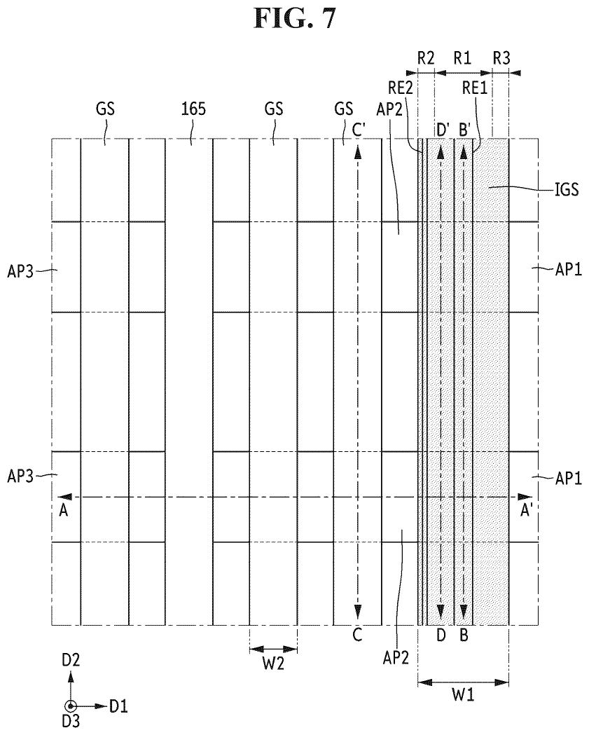

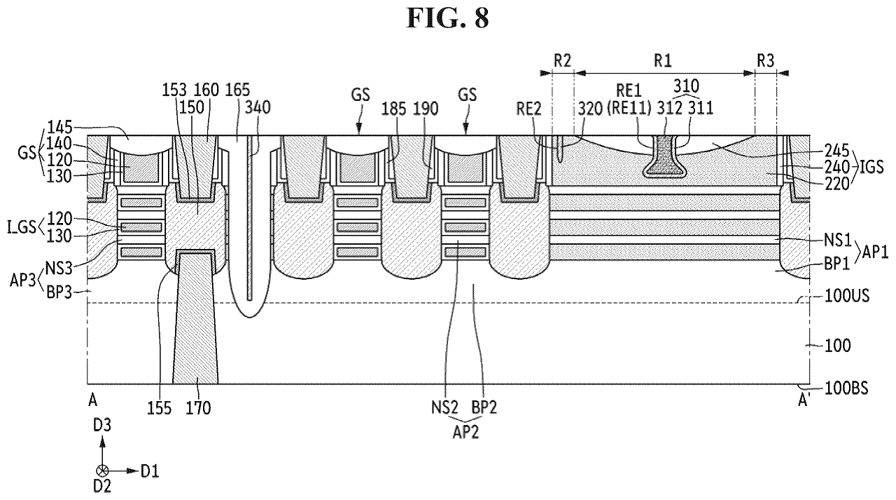

FIG. 7 is an exemplary layout view for explaining the semiconductor device according to one or more embodiments. FIG. 8 is a cross-sectional view taken along A-A′ of FIG. 7. For convenience of explanation, differences from the description using FIGS. 1 through 5 will be mainly described. The cross-sectional views taken along lines B-B′, C-C′, and D-D′ of FIG. 7 may be similar to each of FIGS. 3 through 5.

Referring to FIGS. 7 and 8, in the semiconductor device according to one or more embodiments, the isolation gate structure IGS may include a first recess RE1 formed in the first region R1 and a second recess RE2 formed in the second region R2. That is, a recess may not be formed in the third region R3.

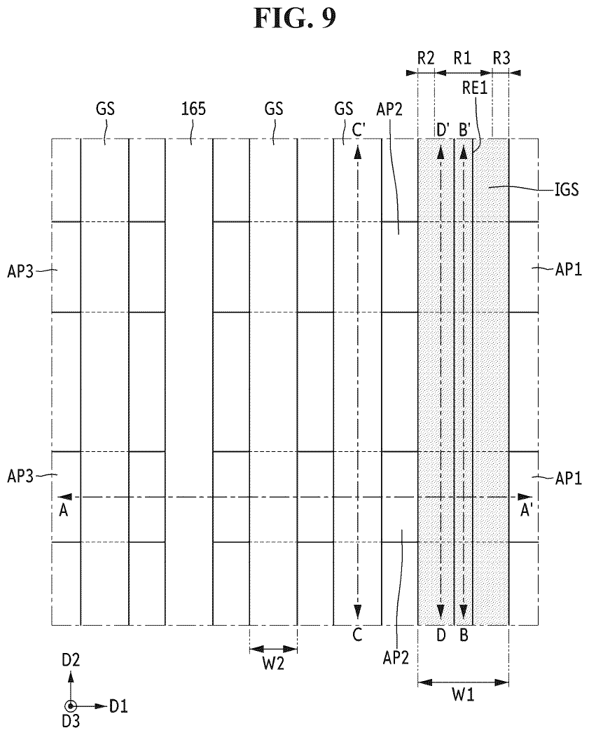

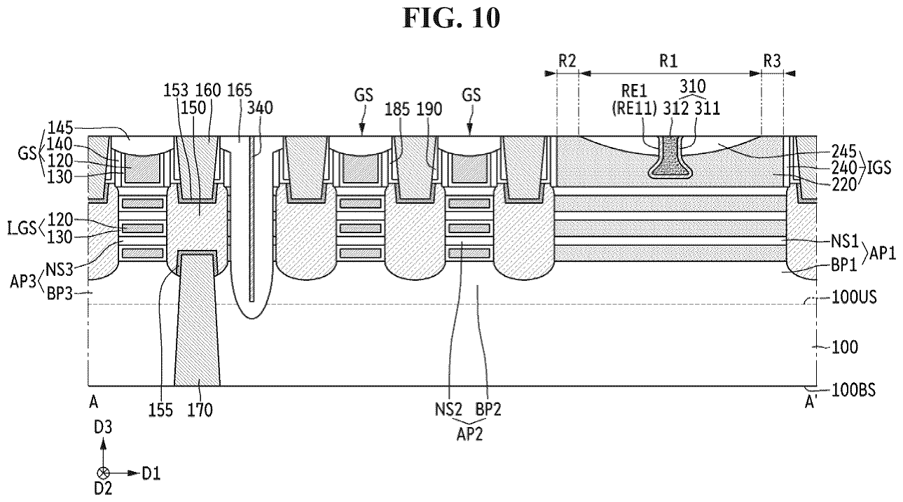

FIG. 9 is an exemplary layout view for explaining the semiconductor device according to one or more embodiments. FIG. 10 is a cross-sectional view taken along line A-A′ of FIG. 9. For convenience of explanation, differences from those described using FIGS. 1 through 5 will be mainly described.

Referring to FIGS. 9 and 10, in the semiconductor device according to one or more embodiments, the isolation gate structure IGS may include a first recess RE1 formed in the first region R1. That is, a recess may not be formed in the second region R2 and the third region R3.

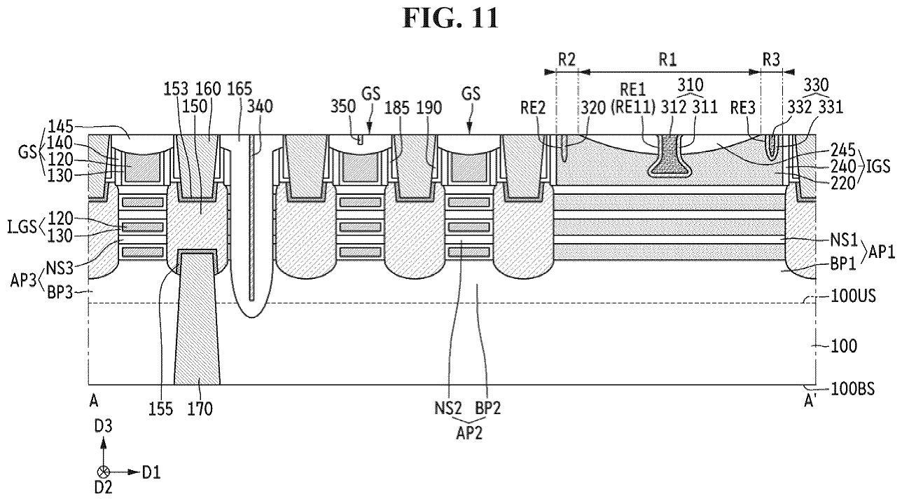

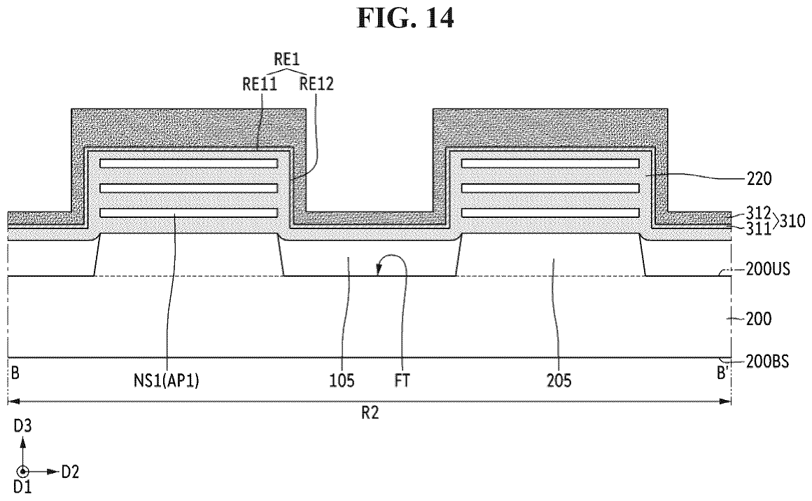

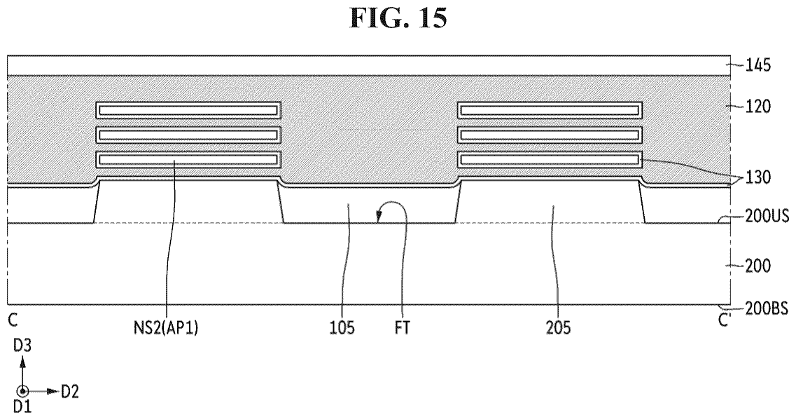

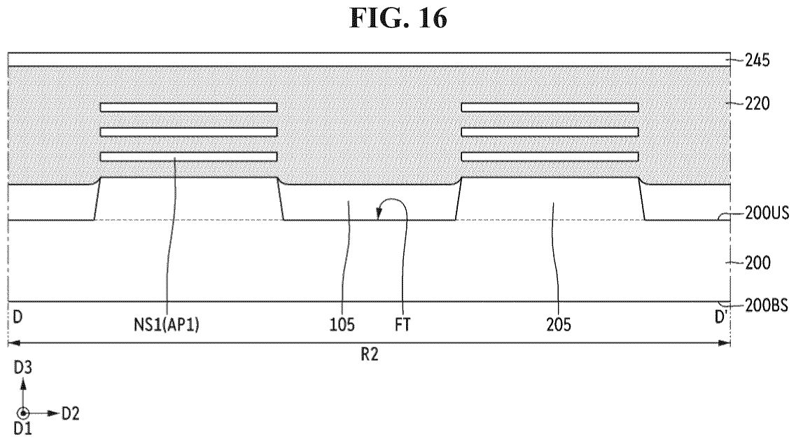

FIGS. 11 through 16 are exemplary layout views for explaining the semiconductor device according to one or more embodiments. For reference, FIGS. 11 through 13 are cross-sectional views taken along line A-A′ of FIG. 1, FIG. 14 is a cross-sectional view taken along line B-B′ of FIG. 1, FIG. 15 is a cross-sectional view taken along line C-C′ of FIG. 1, and FIG. 16 is a cross-sectional view taken along line D-D′ of FIG. 1. For convenience of explanation, differences from those described using FIGS. 1 through 5 will be mainly described.

Referring to FIG. 11, in the semiconductor device according to one or more embodiments, at least one gate structure GS may further include an insulating pattern 350 therein. The insulating pattern 350 may be disposed inside the gate capping pattern 145. The insulating pattern 350 may extend from an upper face of the gate capping pattern 145 into the gate capping pattern 145.

The insulating pattern 350 may include the same material as the first liner film 311.

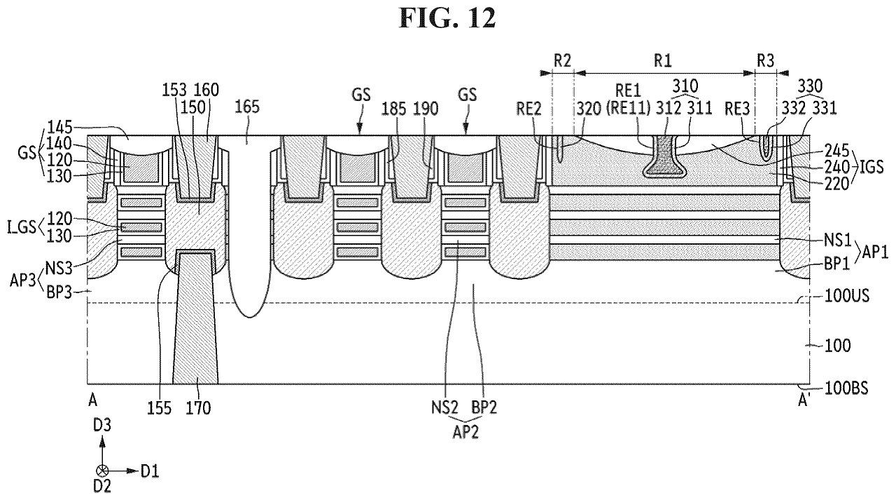

Referring to FIG. 12, in the semiconductor device according to one or more embodiments, the element isolation pattern 165 may not include an insulating pattern (340 of FIG. 2) therein.

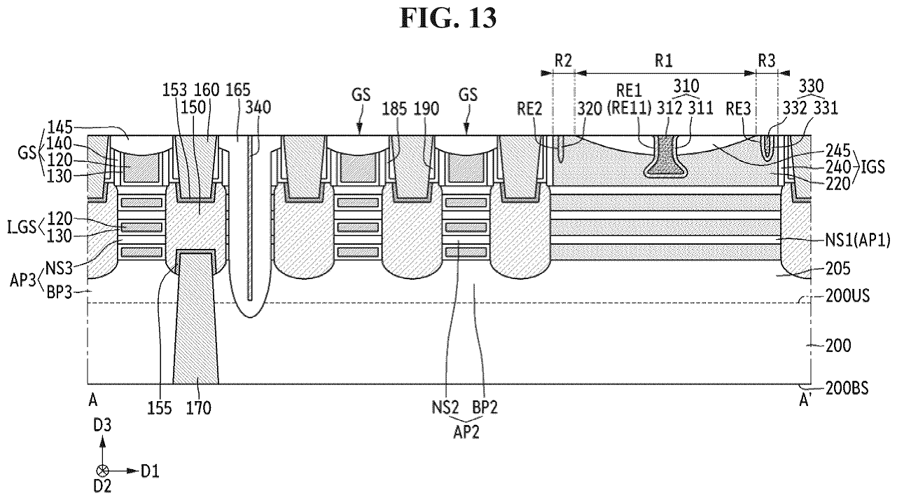

Referring to FIGS. 13 through 16, in the semiconductor memory device according to one or more embodiments, the first active pattern AP1 may include only the first sheet pattern NS1. The second active pattern AP2 may include only the second sheet pattern NS2. The third active pattern AP3 may include only the third sheet pattern NS3. That is, the first active pattern AP1 may not include the first lower pattern (BP1 of FIG. 2). The second active pattern AP2 may not include the second lower pattern (BP2 of FIG. 2). The third active pattern AP3 may not include the third lower pattern (BP3 of FIG. 2).

The back interlayer insulating film 200 may include a third face 200US and a fourth face 200BS that are opposite to each other in the third direction D3. The back interlayer insulating film 200 may include an insulating material. The back interlayer insulating film 200 may include, for example, an oxide film, a dielectric film, or a combination thereof.

The first active pattern AP1, the second active pattern AP2, the third active pattern AP3, the isolation gate structure IGS, the gate structure GS, and the source/drain pattern 150 may be disposed on the third face 200US of the back interlayer insulating film 200.

The back insulating pattern 205 may be disposed on the back interlayer insulating film 200. The back insulating pattern 205 may protrude from the third face 200US of the back interlayer insulating film 200. The back insulating pattern 205 may be a fin-shaped pattern. The back insulating pattern 205 may extend long in the first direction D1.

The back insulating pattern 205 may be defined by a fin trench FT. For example, the third face 200US of the back interlayer insulating film 200 may be a bottom face of the fin trench FT. A side wall of the back insulating pattern 205 may be defined by the fin trench FT. The field insulating film 105 may be disposed on the third face 200US of the back interlayer insulating film 200. The field insulating film 105 may fill at least a part of the fin trench FT. The field insulating film 105 may be disposed on the side wall of the back insulating pattern 205.

The back insulating pattern 205 may be disposed between the first active pattern AP1 and the back interlayer insulating film 200, between the second active pattern AP2 and the back interlayer insulating film 200, and between the third active pattern AP3 and the back interlayer insulating film 200. The back insulating pattern 205 may be disposed between the back interlayer insulating film 200 and the source/drain pattern 150.

The first sheet pattern NS1 may be spaced apart from the back insulating pattern 205 in the third direction D3. The second sheet pattern NS2 may be spaced apart from the back insulating pattern 205 in the third direction D3. The third sheet pattern NS3 may be spaced apart from the back insulating pattern 205 in the third direction D3.

The back insulating pattern 205 may include an insulating material. The back insulating pattern 205 and the back interlayer insulating film 200 may be formed by filling a space from which the first to third lower patterns BP1, BP2, and BP3 and the substrate 100 are removed with an insulating material. For example, the back insulating pattern 205 may include the same material as the back interlayer insulating film 200.

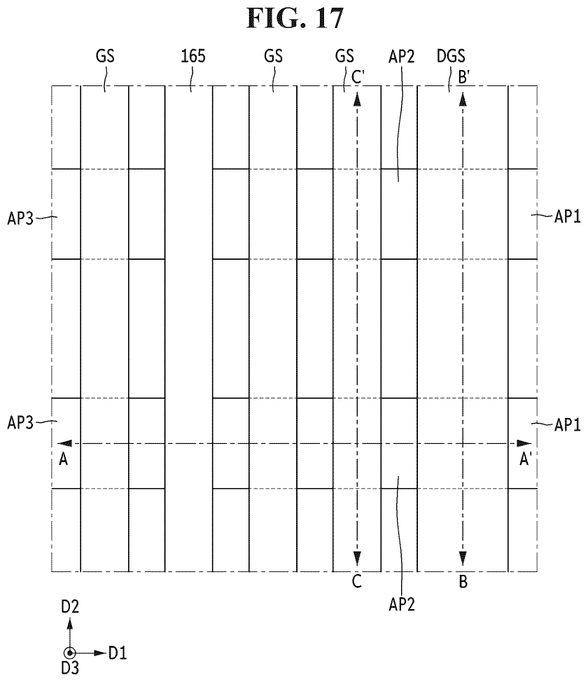

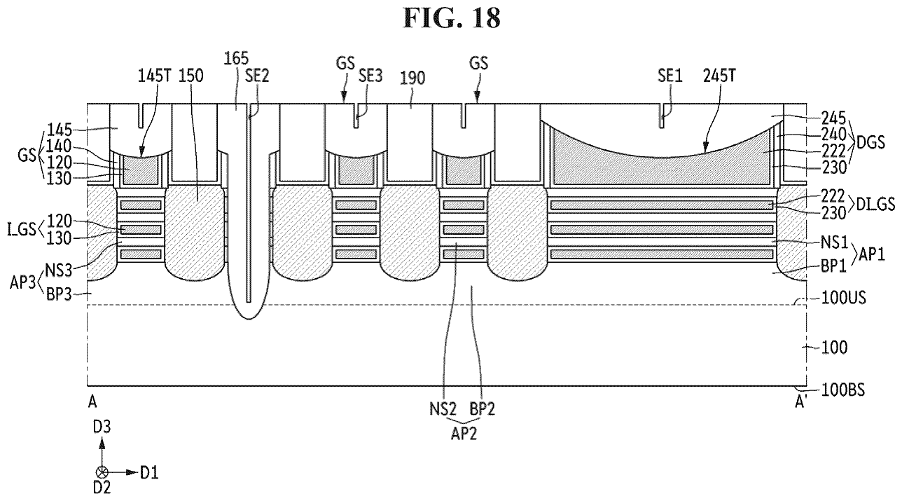

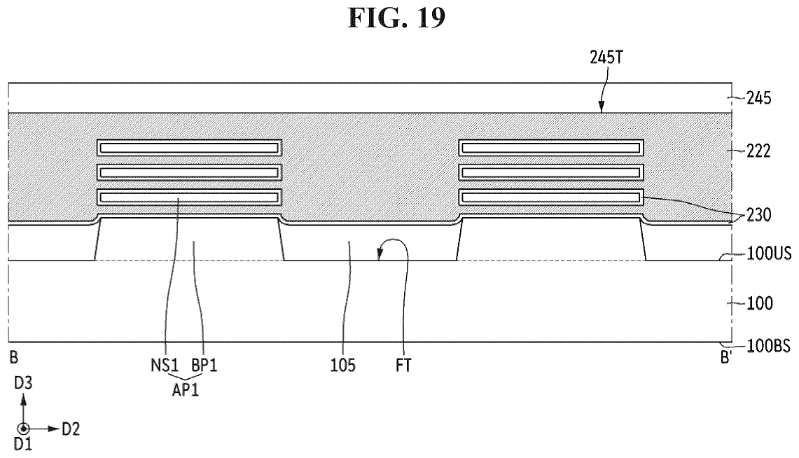

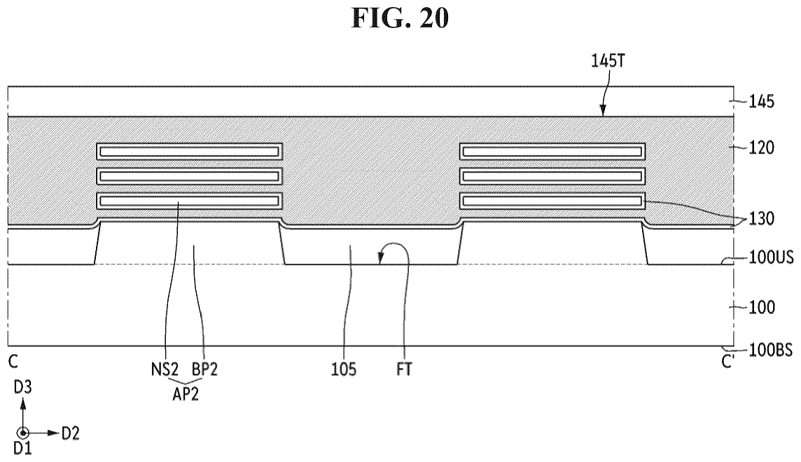

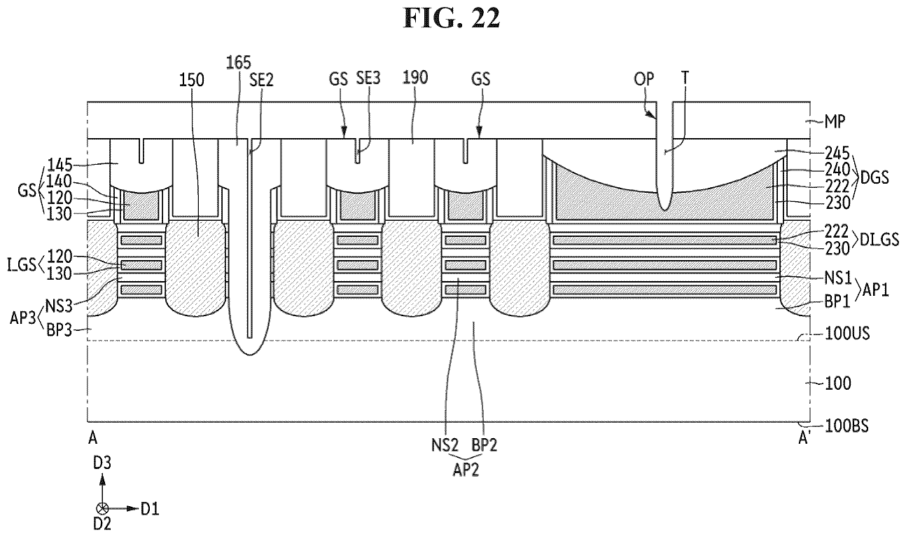

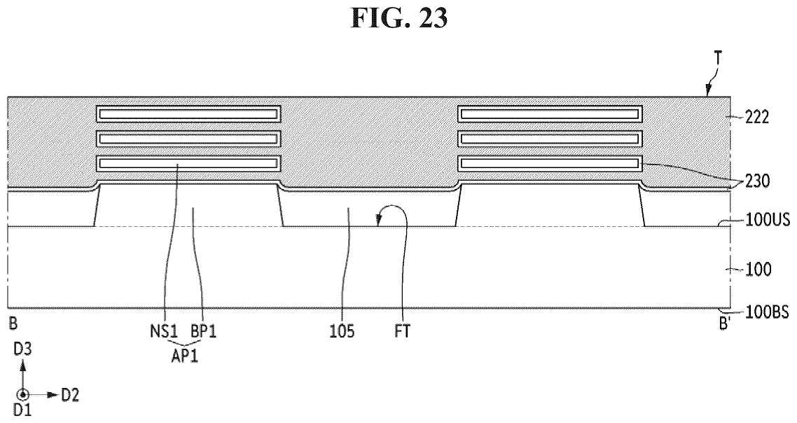

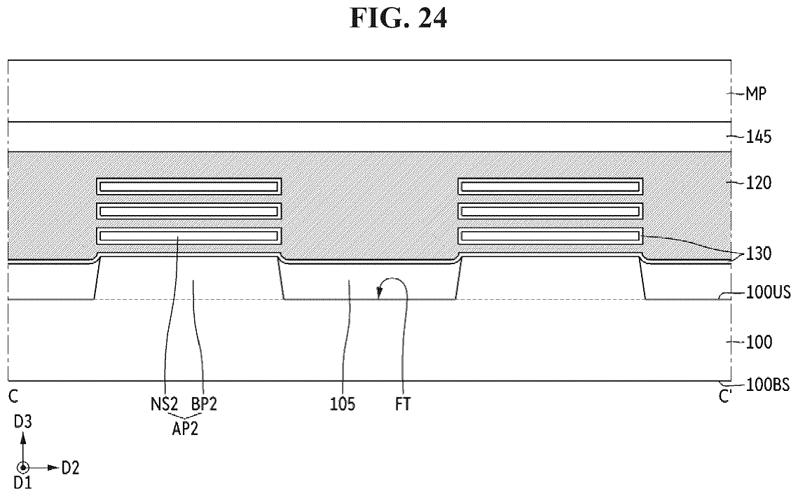

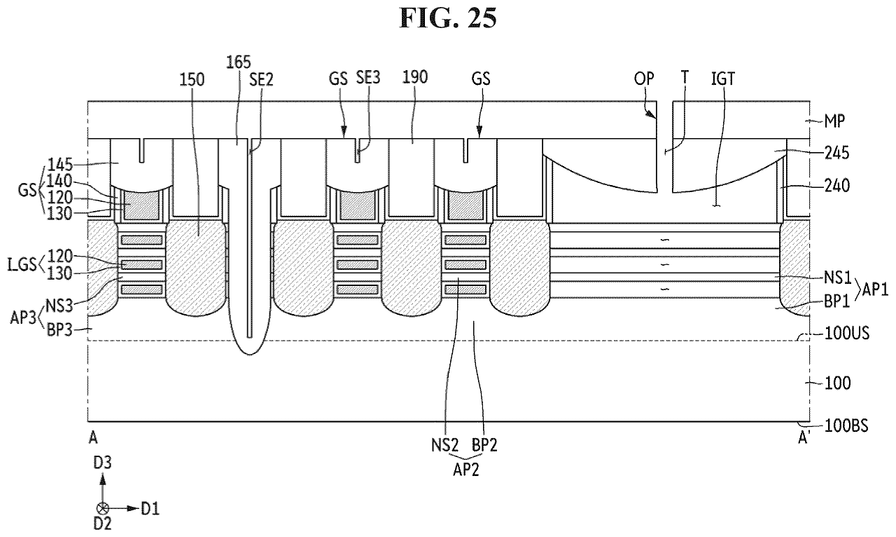

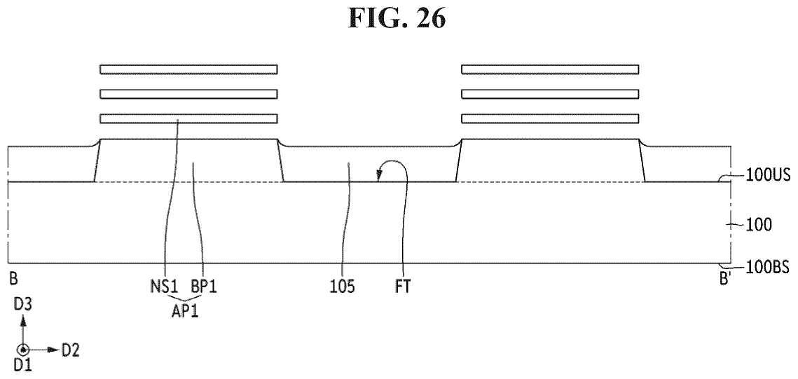

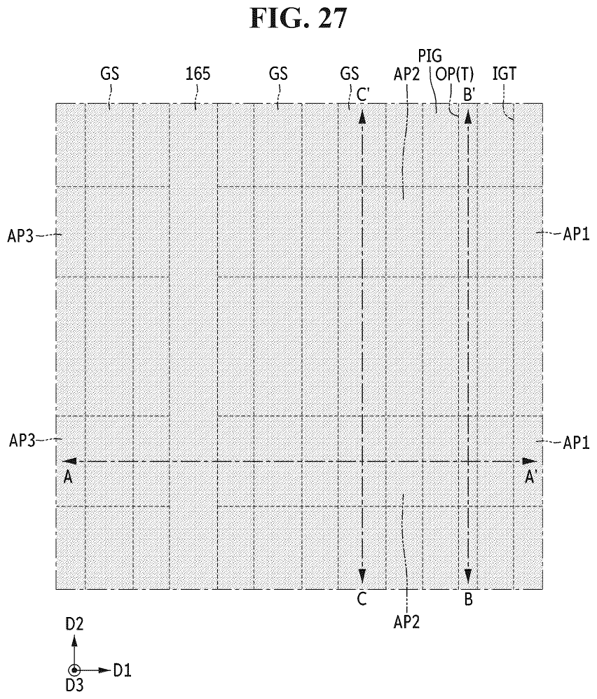

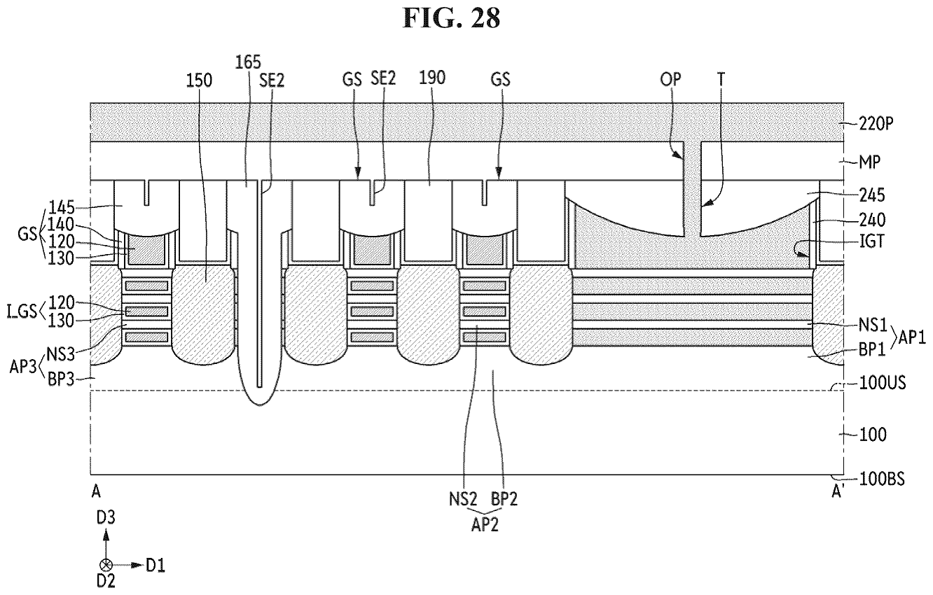

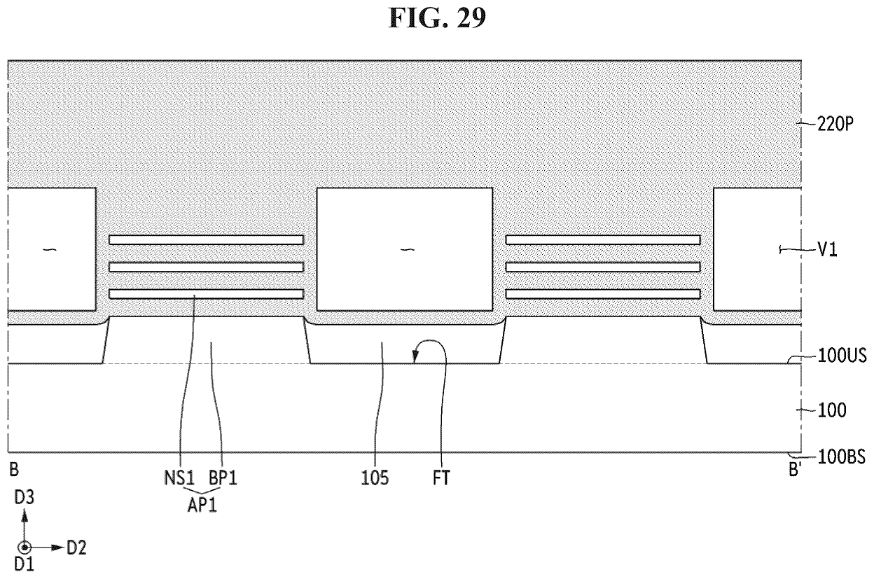

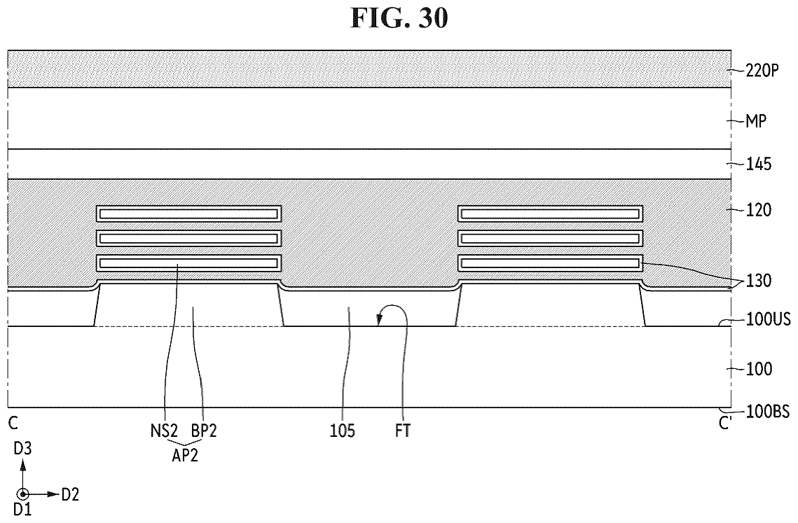

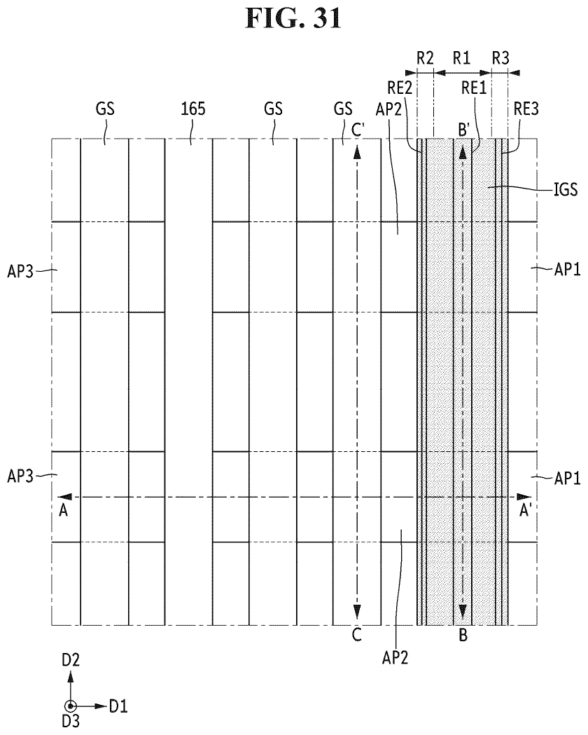

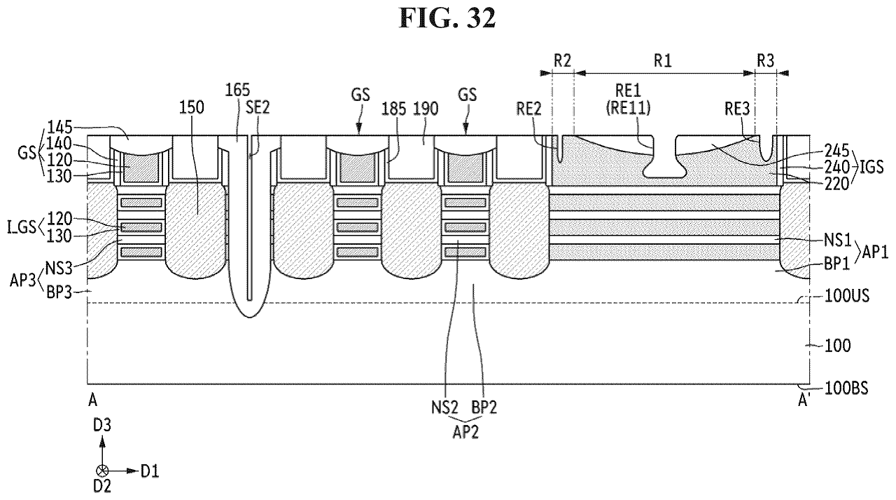

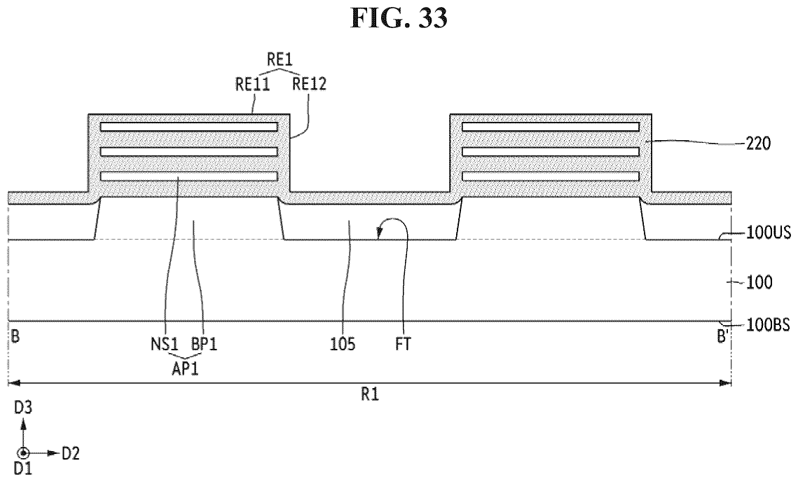

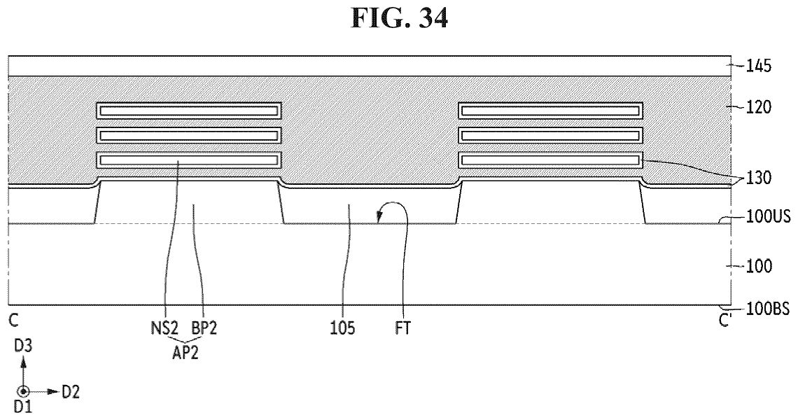

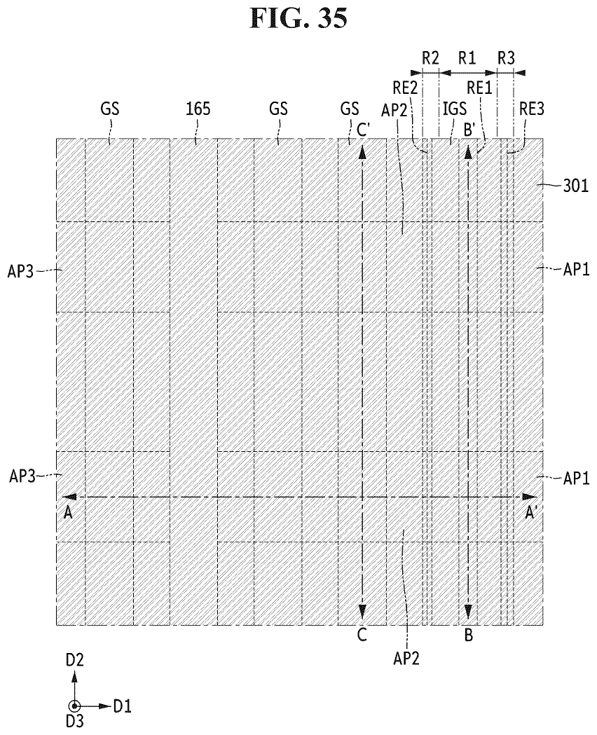

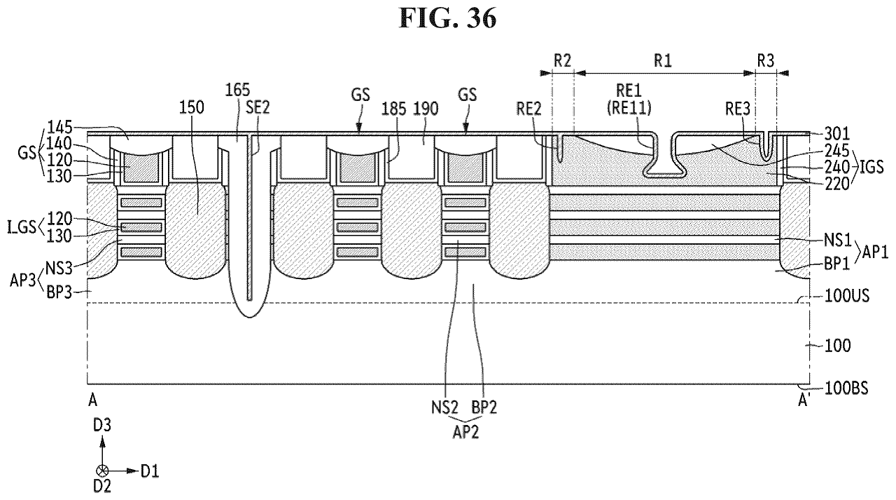

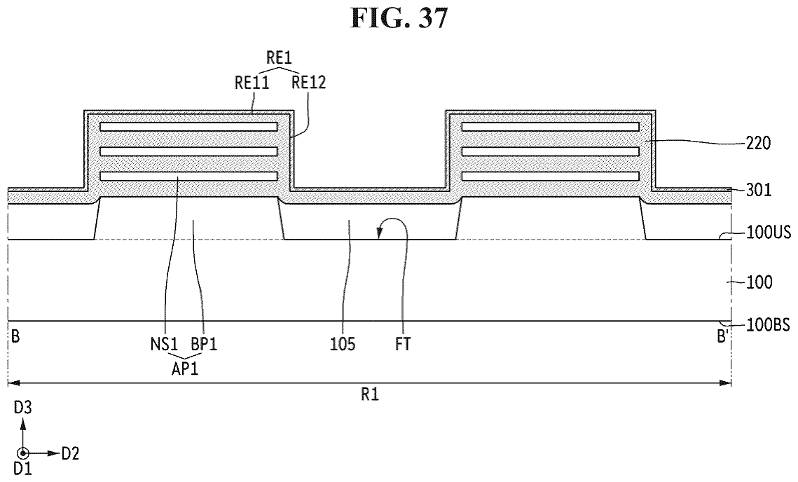

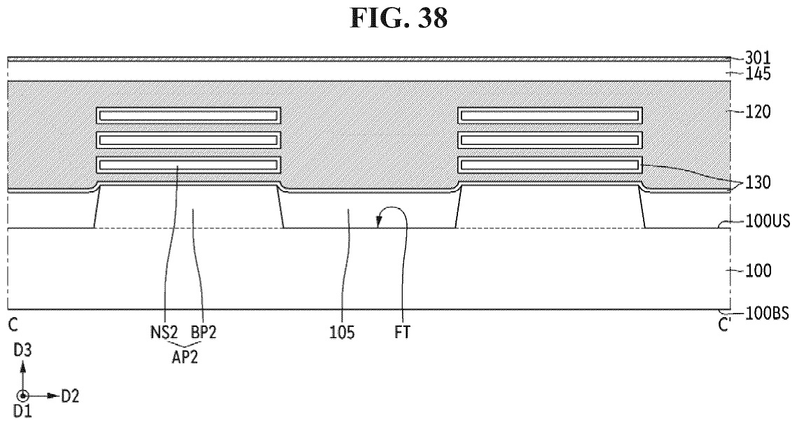

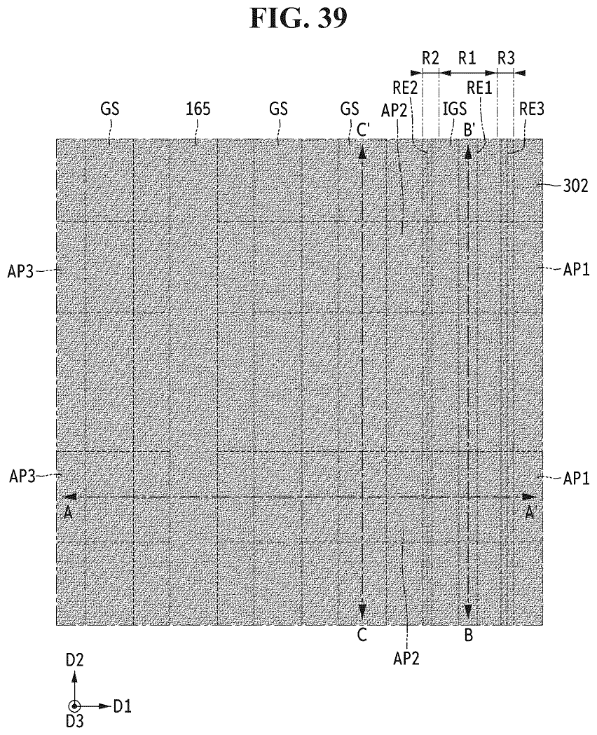

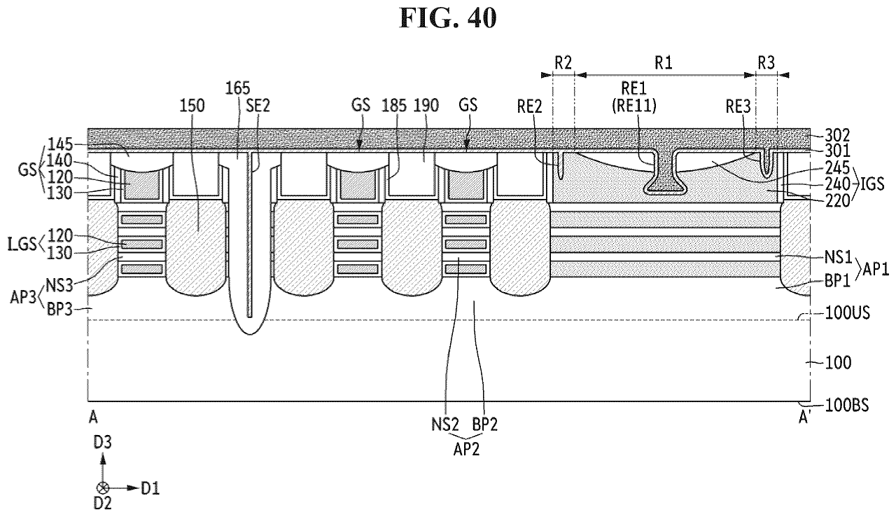

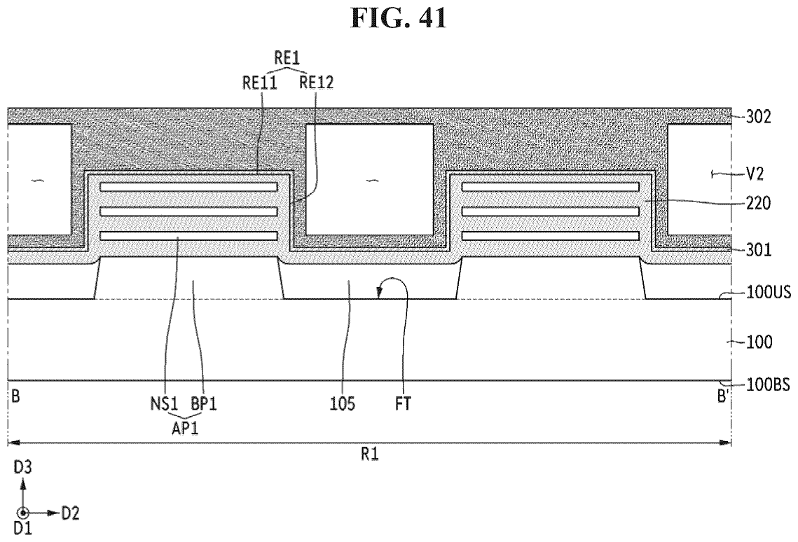

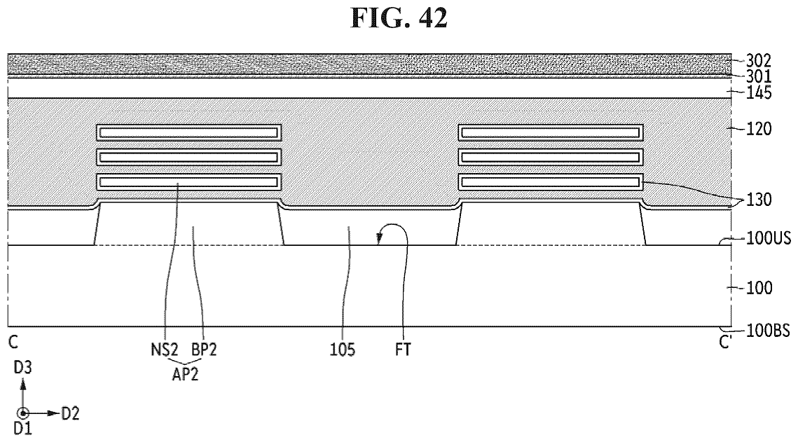

FIGS. 17 through 42 are intermediate stage diagrams for explaining a method for fabricating a semiconductor device according to one or more embodiments. For reference, FIG. 18 is a cross-sectional view taken along line A-A′ of FIG. 17, FIG. 19 is a cross-sectional view taken along line B-B′ of FIG. 17, and FIG. 20 is a cross-sectional view taken along line C-C′ of FIG. 17. FIGS. 22 and 25 are cross-sectional views taken along line A-A′ of FIG. 18, FIGS. 23 and 26 are cross-sectional views taken along line B-B′ of FIG. 18, and FIG. 24 is a cross-sectional view taken along line C-C′ of FIG. 18. FIG. 28 is a cross-sectional view taken along line A-A′ of FIG. 27, FIG. 29 is a cross-sectional view taken along line B-B′ of FIG. 27, and FIG. 30 is a cross-sectional view taken along line C-C′ of FIG. 27. FIG. 32 is a cross-sectional view taken along line A-A′ of FIG. 31, FIG. 33 is a cross-sectional view taken along line B-B′ of FIG. 31, and FIG. 34 is a cross-sectional view taken along line C-C′ of FIG. 31. FIG. 36 is a cross-sectional view taken along line A-A′ of FIG. 35, FIG. 37 is a cross-sectional view taken along line B-B′ of FIG. 35, and FIG. 38 is a cross-sectional view taken along line C-C′ of FIG. 35. FIG. 40 is a cross-sectional view taken along line A-A′ of FIG. 39, FIG. 41 is a cross-sectional view taken along line B-B′ of FIG. 39, and FIG. 42 is a cross-sectional view taken along line C-C′ of FIG. 39.

Referring to FIGS. 17 and 20, first to third active patterns AP1, AP2, and AP3 may be formed on the substrate 100.

The source/drain pattern 150 may be formed on the substrate 100. Before the source/drain pattern 150 is formed, the gate spacer 140 may be formed on the second and third lower patterns BP2 and BP3, and the isolation spacer 240 may be formed on the first lower pattern BP1. The isolation spacer 240 may be formed through the same process as the gate spacer 140. The isolation spacer 240 may include the same material as the gate spacer 140.

The front interlayer insulating film 190 may be formed on the source/drain pattern 150.

Next, the first sheet pattern NS1 may be formed on the first lower pattern BP1, the second sheet pattern NS2 may be formed on the second lower pattern BP2, and the third sheet pattern NS3 may be formed on the third lower pattern BP3. Accordingly, the first to third active patterns AP1, AP2, and AP3 may be formed on the first face 100US of the substrate 100.

Next, a dummy gate structure DGS that surrounds the first sheet pattern NS1 may be formed on the first lower pattern BP1, a gate structure GS that surrounds the second sheet pattern NS2 may be formed on the second lower pattern BP2, and a gate structure GS that surrounds the third sheet pattern NS3 may be formed on the third lower pattern BP3.

The dummy gate structure DGS may include a dummy gate insulating film 230 and a dummy gate electrode 222. The isolation capping pattern 245 may be formed on the dummy gate electrode 222. An upper face of the isolation capping pattern 245 may be placed in the same plane as an upper face of the front interlayer insulating film 190.

The dummy gate structure DGS may include a dummy inner gate structure DI_GS. The dummy inner gate structure DI_GS may be disposed between the first sheet patterns NS1 adjacent to each other in the third direction D3, and between the first lower pattern BP1 and the first sheet pattern NS1 that are adjacent to each other in the third direction D3. The inner gate structure I_GS may be disposed between the upper face of the first lower pattern BP1 and the lower face of the first sheet pattern NS1 that face each other in the third direction D3, and between the upper face of the first sheet pattern NS1 and the lower face of the first sheet pattern NS1 that face each other in the third direction D3.

The dummy inner gate structure DI_GS may include a dummy gate electrode 222 and a dummy gate insulating film 230. The number of dummy inner gate structures DI_GS included in one dummy gate structure DGS may be the same as the number of the plurality of first sheet patterns NS1.

The dummy gate structure DGS may be formed through the same process as the gate structure GS. Each of the dummy gate electrode 222, the dummy gate insulating film 230, and the isolation capping pattern 245 may include the same material as each of the gate electrode 120, the gate insulating film 130, and the gate capping pattern 145.

The isolation capping pattern 245 may include a first seam SE1 therein. The gate capping pattern 145 may include a third seam SE3 therein. The first seam SE1 and the third seam SE3 may be formed in the process of forming the isolation capping pattern 245 and the Gate Capping Pattern 145.

For example, the gate capping trench 245 T may be formed by removing a part of the gate insulating film 130, a part of the gate spacer 140, and a part of the source/drain etching stop film 185. The isolation capping trench 145 T may be formed by removing a part of the dummy gate insulating film 230, a part of the isolation spacer 240, and a part of the source/drain etching stop film 185. A preliminary capping film which fills the gate capping trench 245 T and the isolation capping trench 145 T and covers the front interlayer insulating film 190 may be formed. The preliminary capping film inside the isolation capping trench 145 T and the preliminary capping film inside the gate capping trench 245 T may include a seam. Next, a planarization process may be performed on the preliminary capping film. As a result, an isolation capping pattern 245 that fills the isolation capping trench 145 T and includes the first seam SE1, and a gate capping pattern 145 that fills the gate capping trench 245 T and includes the third seam SE3 may be formed.

Alternatively, the preliminary capping film inside the gate capping trench 245 T may not have a seam formed therein. The gate capping pattern 145 may not have the third seam SE3 formed therein.

The bottom face of the isolation capping trench 145 T and the bottom face of the gate capping trench 245 T may be convex toward the substrate 100. Since the width of the first sheet pattern NS1 in the first direction D1 is greater than the widths of the second and third sheet patterns NS2 and NS3 in the first direction D1, the extent of convexity of the bottom face of the isolation capping trench 145 T may be greater than the extent of convexity of the bottom face of the gate capping trench 245 T. Unlike the shown example, the bottom face of the gate capping trench 245 T may be flat.

The element isolation pattern 165 may be formed. The element isolation pattern 165 may include the second seam SE2 therein. For example, the gate structure between the first active pattern AP1 and the second active pattern AP2 may be removed, a trench which penetrates the sheet patterns between the first sheet pattern NS1 and the second sheet pattern NS2 may be formed, and a preliminary isolation film which fills the trench and covers the front interlayer insulating film 190, the gate structure GS, and the dummy gate structure DGS may be formed. The preliminary isolation film may be formed, for example, through an atomic layer deposition (ALD) process. The preliminary isolation film inside the trench may include a seam. Next, a planarization process may be performed on the preliminary capping film. Accordingly, the element isolation pattern 165 which fills the trench and includes the second seam SE2 may be filled.

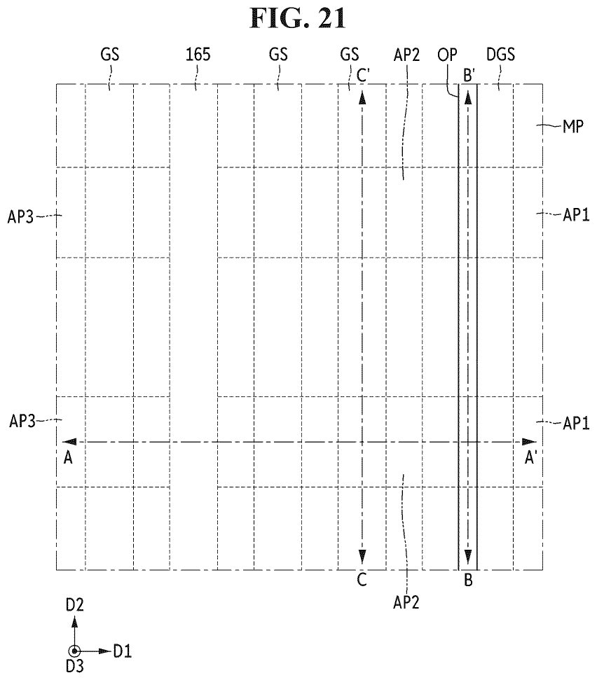

Referring to FIGS. 21 through 24, a mask pattern MP including an opening OP may be formed. The opening OP may expose an upper face of the dummy gate structure DGS. The opening OP may expose an upper face of the isolation capping pattern 245. The opening OP may extend in the second direction D2.

A trench T may be formed in the dummy gate structure DGS, using the mask pattern MP. The trench T may be formed at a position corresponding to the mask pattern MP. The trench T may extend in the second direction D2. The trench T may extend from an upper face of the isolation capping pattern 245 into the dummy gate electrode 222. The bottom face of the trench T may be disposed inside the dummy gate electrode 222.

Referring to FIGS. 25 and 26, the dummy gate electrode (222 of FIGS. 22 through 24) and the dummy gate insulating film (230 of FIGS. 22 through 24) may be removed through the trench T to form the isolation gate trench IGT.

Referring to FIGS. 27 through 30, a preliminary isolation gate electrode 220P may be formed on the mask pattern MP. The preliminary isolation gate electrode 220P may be formed in the isolation gate trench IGT and the trench T.

The preliminary isolation gate electrode 220P may fill a part of the isolation gate trench IGT. The preliminary isolation gate electrode 220P may fill a gap between the first lower pattern BP1 and the first sheet pattern NS1 that are adjacent to each other in the third direction D3, and a gap between the adjacent first sheet patterns NS1. The preliminary isolation gate electrode 220P may surround the first sheet pattern NS1.

The preliminary isolation gate electrode 220P may include a first void V1 therein. The first void V1 may be formed on the field insulating film 105. The first void V1 may overlap the field insulating film 105 in the third direction D3. The preliminary isolation gate electrode 220P may fill the trench T.

Referring to FIGS. 31 through 34, a planarization process may be performed on the preliminary isolation gate electrode (220P of FIGS. 27 through 30). At this time, a part of the gate capping pattern 145, a part of the isolation capping pattern 245, and a part of the front interlayer insulating film 190 may be etched together. Accordingly, the isolation capping pattern 245 may be formed on a part of the isolation gate electrode 220. This may be due to that fact that the bottom face of the isolation capping trench 145 T is convex in FIGS. 17 through 20. The isolation gate electrode 220 including the first to third regions R1, R2, and R3 may be formed. The isolation gate structure IGS including the isolation gate electrode 220, the isolation capping pattern 245, and the isolation spacer 240 may be formed.

The second seam (SE2 of FIG. 28) of the gate capping pattern 145 may be removed.

Alternatively, the second seam SE2 of the gate capping pattern 145 may remain.

After the planarization process is performed, a cleaning process may be performed. The particles and various impurities remaining on the semiconductor device may be removed by the aforementioned cleaning process. The cleaning process may use, for example, DHF as a cleaning solution. At this time, a part of the exposed isolation gate electrode 220 may be etched to form the first to third recesses RE1, RE2, and RE3. A part of the isolation gate electrode 220 exposed by the trench (T of FIGS. 27 through 30) may be etched to form a first recess RE1. A part of the isolation gate electrode 220 of the second region R2 exposed by the isolation capping pattern 245 may be etched to form a second recess RE2. A part of the isolation gate electrode 220 of the third region R3 exposed by the isolation capping pattern 245 may be etched to form a third recess RE3.

Alternatively, a recess may be formed in only one of the second region R2 and the third region R3, or a recess may be formed in both the second region R2 and the third region R3.

Referring to FIGS. 35 through 38, a first film 301 may be formed. The first film 301 may be formed along the first recess RE1, the second recess RE2, the third recess RE3, the upper face of the gate structure GS, the upper face of the isolation gate structure IGS, and the upper face of the element isolation pattern 165.

In the cross-sectional view in which the first active pattern AP1 is taken along the first direction D1, the first film 301 may fill the second recess RE2 or the third recess RE3, depending on the thickness of the first film 301, the width of the second recess RE2 in the first direction D1, and the width of the third recess RE3 in the first direction D1. For example, in the cross-sectional view in which the first active pattern AP1 is taken along the first direction D1, the first film 301 may fill the second recess RE2 and may extend along the first recess RE1 and the third recess RE3. Alternatively, in the cross-sectional view in which the first active pattern AP1 is taken along the first direction D1, the first film 301 may fill the second recess RE2 and the third recess RE3. Alternatively, in the cross-sectional view in which the first active pattern AP1 is taken along the first direction D1, the first film 301 may extend along the second recess RE2 and the third recess RE3. Alternatively, in the cross-sectional view in which the first active pattern AP1 is taken along the first direction D1, the first film 301 may fill the second recess RE2 and may extend along the third recess RE3.

The first film 301 may fill the second seam SE2 of the element isolation pattern 165.

Alternatively, when the third seam (SE3 of FIG. 28) remains inside the gate capping pattern 145, the first film 301 may fill the third seam (SE3 of FIG. 28). Thus, referring to FIG. 11, the gate capping pattern 145 including the insulating pattern 350 therein may be formed. The insulating pattern 350 may be the first film 301 that fills the third seam (SE3 of FIG. 28).

The etching resistance of the first film 301 to DHF may be greater than the etching resistance to the isolation gate electrode 220 and the etching resistance to the second film 302. The first film 301 may include, for example, SiN, SiCN, SiOCN, SiCOH, SiOCH, or the like.

Referring to FIGS. 39 through 42, the second film 302 may be formed on the first film 301. The second film 302 may include a second void V2 therein. The second void V2 may be formed on the field insulating film 105. The second void V2 may overlap the field insulating film 105 in the third direction D3. In the cross-sectional view in which the first active pattern AP1 is taken along the first direction D1, the second film 302 may fill the first recess RE1 and the third recess RE3.

The second film 302 may include a different material from the first film 301. The second film 302 may include the same material as the isolation gate electrode 220. The second film 302 may include, for example, silicon oxide.

Referring to FIGS. 1 through 5, the front source/drain contact 160 may be formed on the source/drain pattern 150.

Referring to FIGS. 39 through 42 and FIGS. 1 through 5, for example, a hole which penetrates the first film 301, the second film 302, the front interlayer insulating film 190, and the source/drain etching stop film 185 may be formed, and a preliminary conductive film which fills the hole and covers the second film (302 of FIGS. 39 through 42) may be formed. A planarization process may be performed on the preliminary conductive film. As a result, the front source/drain contact 160 may be formed.

At this time, a part of the first film 301 and a part of the second film 302 may be etched together. As a result, the first to third insulating patterns 310, 320 and 330 and the insulating pattern 340 may be formed. The first liner film 311, the second insulating pattern 320, the second liner film 331, and the insulating pattern 340 may be formed by patterning the first film 301. The first filling film 312 and the second filling film 332 may be formed by patterning the second film 302.

After the planarization process is performed, a cleaning process may be performed. The particles and various impurities remaining on the semiconductor device may be removed by the cleaning process. The cleaning process may use, for example, DHF (diluted HF) or the like as a cleaning solution.

At this time, the etching resistance of the first film 301 to the cleaning solution may be greater than the etching resistance of the isolation gate electrode 220 and the etching resistance of the second film 302. That is, since the first liner film 311, the second liner film 331, and the second insulating pattern 320 include a material having etching resistance to the cleaning solution, the isolation gate electrode 220 may not be consumed in the cleaning process. In addition, since the first to third insulating patterns 310, 320, and 330 are formed in the first to third recesses RE1, RE2, and RE3, a conductive material may not be formed in the first to third recesses RE1, RE2, and RE3. Therefore, it is possible to prevent deterioration of the electrical characteristics of the diode formed on the first active pattern AP1, and to provide a semiconductor device having improved reliability.

Thereafter, the back source/drain contact 170 may be formed.

Although one or more embodiments of the present disclosure have been described above with reference to the accompanying drawings, the present disclosure is not limited to the foregoing embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A semiconductor device comprising:
a first active pattern which extends in a first direction;
an isolation gate electrode on the first active pattern, wherein the isolation gate electrode comprises an insulating material and extends in a second direction intersecting the first direction;
an isolation capping pattern on the isolation gate electrode;
a first recess in the isolation capping pattern and the isolation gate electrode; and
a first insulating pattern inside the first recess, wherein the first insulating pattern comprises a first liner film and a first filling film,
wherein the first liner film comprises a material different from the isolation gate electrode and the first filling film.

2. The semiconductor device of claim 1, wherein the first insulating pattern fills the first recess.

3. The semiconductor device of claim 1, further comprising:
a second recess in the isolation gate electrode; and
a second insulating pattern inside the second recess,
wherein the second insulating pattern comprises a material different from the isolation gate electrode.

4. The semiconductor device of claim 3, wherein the second insulating pattern fills the second recess.

5. The semiconductor device of claim 3, wherein the second insulating pattern comprises the same material as the first liner film.

6. The semiconductor device of claim 1, further comprising:
a second recess in the isolation gate electrode; and
a second insulating pattern inside the second recess, wherein the second insulating pattern comprises a second liner film and a second filling film inside the second recess,
wherein the second liner film comprises a material different from the isolation gate electrode and the second filling film.

7. The semiconductor device of claim 6,
wherein the second liner film comprises the same material as the first liner film, and
wherein the second filling film comprises the same material as the first filling film.

8. The semiconductor device of claim 1, further comprising:
a second active pattern which extends in the first direction;
an element isolation pattern between the first active pattern and the second active pattern; and
a second insulating pattern inside the element isolation pattern,
wherein the second insulating pattern comprises the same material as the first liner film.

9. The semiconductor device of claim 1, further comprising:
a second active pattern which extends in the first direction;
a gate electrode on the second active pattern, wherein the gate electrode extends in the second direction;
a gate capping pattern on the gate electrode; and
a second insulating pattern inside the gate capping pattern,
wherein the second insulating pattern comprises the same material as the first liner film.

10. The semiconductor device of claim 1, further comprising:
a second active pattern which extends in the first direction; and
a gate electrode on the second active pattern,
wherein the gate electrode extends in the second direction, and
wherein a width of the isolation gate electrode in the first direction is greater than a width of the gate electrode in the first direction.

11. The semiconductor device of claim 1, further comprising:
a second recess in the isolation gate electrode;
a second insulating pattern inside the second recess;
a third recess in the isolation gate electrode; and
a third insulating pattern inside the third recess,
wherein the first recess is between the second recess and the third recess.

12. A semiconductor device comprising:
a plurality of first active patterns which extend in a first direction, wherein the plurality of first active patterns are spaced apart from each other in a second direction;
an isolation gate electrode on the plurality of first active patterns, wherein the isolation gate electrode extends in the second direction;
a liner film which extends along the isolation gate electrode;
a filling film which extends along the liner film;
a plurality of second active patterns which extend in the first direction, wherein the plurality of second active patterns are spaced apart from each other in the second direction; and
a gate structure on the plurality of second active patterns, wherein the gate structure extends in the second direction,
wherein the gate structure fills gaps formed between second active patterns, among the plurality of second active patterns, that are adjacent to one another in the second direction, and
wherein the isolation gate electrode, the liner film, and the filling film fill a part of gaps formed between first active patterns, among the plurality of first active patterns, that are adjacent to one another in the second direction.

13. The semiconductor device of claim 12, wherein the filling film comprises a material different from the liner film.

14. The semiconductor device of claim 12, wherein the liner film comprises a material different from the isolation gate electrode.

15. The semiconductor device of claim 12, further comprising:
a substrate,
wherein each of the plurality of first active patterns and each of the plurality of second active patterns comprises: a lower pattern protruding from the substrate; and a plurality of sheet patterns spaced apart from the lower pattern.

16. The semiconductor device of claim 12, further comprising:
a lower interlayer insulating film; and
an insulating pattern which protrudes from the lower interlayer insulating film,
wherein each of the plurality of first active patterns and each of the plurality of second active patterns comprises a plurality of sheet patterns spaced apart from the insulating pattern.

17. A semiconductor device comprising:
a first active pattern;
an isolation gate structure which intersects the first active pattern, wherein the isolation gate structure comprises a first region and a second region;
a recess in at least one of the first region and the second region; and
an insulating pattern extending along the recess,
wherein the isolation gate structure comprises an isolation gate electrode and an isolation capping pattern on the isolation gate electrode,
wherein an upper face of the first region of the isolation gate structure is defined by the isolation capping pattern, and
wherein an upper face of the second region of the isolation gate structure is defined by the isolation gate electrode.

18. The semiconductor device of claim 17,
wherein the recess comprises a first recess in the first region and a second recess in the second region,
wherein the insulating pattern comprises a first insulating pattern extending along the first recess and a second insulating pattern extending along the second recess, and
wherein each of the first insulating pattern and the second insulating pattern comprises a multi-layer film.

19. The semiconductor device of claim 17,
wherein the recess comprises a first recess in the first region and a second recess in the second region,
wherein the insulating pattern comprises a first insulating pattern extending along the first recess and a second insulating pattern extending along the second recess,
wherein the first insulating pattern comprises a multi-layer film, and
wherein the second insulating pattern comprises a single film.

20. The semiconductor device of claim 17,
wherein the recess comprises a first recess in the first region and a second recess in the second region, and
wherein a depth of the second recess is deeper than a depth of the first recess.
